(19) United States
(12) Patent Application Publication
(10) Pub. No.: US 2006/0211236 A1
(43) Pub. Date: Sep. 21, 2006

(54) Surface-coating method, production of microelectronic interconnections using said method and integrated circuits

(75) Inventors: Christophe Bureau, Suresnes (FR); Paul-Henri Haumesser, Saint Cassien (FR); Sylvain Maitrejean, Grenoble (FR); Thierry Mourier, Meylan (FR)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: ALCHIMER S.A. 15, rue du Buisson aux Fraises- ZI, MASSY (FR)

(21) Appl. No.: 10/544,651

(22) PCT Filed: Feb. 13, 2004
(86) PCT No.: PCT/FR04/50057

§ 371 Date: Aug. 5, 2005

(30) Foreign Application Priority Data
Feb. 17, 2003 (FR) 03/01873

(51) Int. Cl. H01L 21/4763

(52) U.S. Cl. 438/628

(57) ABSTRACT

The present invention relates to a process for coating a surface of a substrate with a seed film of a metallic material, the said surface being an electrically conductive or semiconductive surface and having recesses and/or projections. The process comprises the following: an organic film is placed on the said surface, the said film having a thickness such that the free face of this film conformally follows the recesses and/or projections of the said electrically conductive or semiconductive surface on which it is placed; a precursor of the metallic material is inserted within the said organic film placed on the said surface at the same time as, or after, the step consisting in placing the said organic film on the said surface; and the said precursor of the metallic material inserted within the said organic film is converted into the said metallic material. This process allows integrated circuits, interconnects in microelectronics and microsystems to be fabricated.

### TECHNICAL FIELD

The present invention relates to a process for coating a surface of a substrate with a film for nucleating a metallic material, to a process for fabricating interconnects in microelectronics, and to microelectronic interconnection elements, electronic microsystems and integrated circuits obtained by these processes.

The surfaces involved in the present invention have the particular feature of being electrically conductive or semiconductive surfaces and of having recesses and/or projections, which are for example microetched features, for example interconnection holes or vias intended for the production of microelectronic systems, for example integrated circuits.

The invention relates in general to a process for the uniform—and especially conformal—deposition of metal layers on electrically conductive or semiconductive surfaces, and to their applications, especially to the processes and methods for fabricating integrated circuits and more particularly to the formation of networks of metal interconnects, for example those based on copper, and also to processes and methods for fabricating Microsystems and connectors.

### PRIOR ART

In what follows, the prior art is restricted to the microelectronics field as this is representative of both devices and processes currently available for uniform metal deposition and of the increasing technical difficulties in obtaining uniform—and especially conformal—metal coatings as the demand for faster processors and ever finer etching becomes more pressing. A person skilled in the art may therefore easily transpose these problems to other applications, such as microsystems or connectors, the problem being the same at a simply different scale. At the very most, new constraints, especially cost constraints, are appearing that mean that certain processes and devices described below for microelectronics cannot be applied in these fields.

Integrated circuits are fabricated by forming discrete semiconductor devices on the surface of silicon wafers. A metallurgical interconnection network is then produced on these devices, so as to make contact between their active elements and to produce, between them, the wiring needed to obtain the desired circuit. A system of interconnects is formed from various levels. Each level is formed by metal lines and these lines are joined together by contacts called “interconnect holes” or “vias”.

The technical development of Microsystems has led to an increase in integration density and consequently a reduction in component size. The length of the interconnects has increased and their width has decreased, as has also the spacing between the lines. When these interconnects are made of aluminium or tungsten, they therefore result in increasingly unacceptable resistances as their size decreases. This is because such high resistances increase the impedance of the circuits, increase the electrical signal propagation times and they limit the clock speeds of micro-processors. In addition, at high current densities aluminium is liable to undergo electromigration. This may occur in conductors of very small cross section and may cause discontinuities, leading to circuit malfunctions.

The conductivity of copper, which is higher than that of aluminium, tungsten or other conducting materials used in integrated circuits, is a major advantage, and the reason why it is used to produce metal interconnects. Copper is also more resistant to the phenomenon of electromigration. For manufacturers of ULSI-ICs (Ultra-Large-Scale-Integration Integrated Circuits) these two criteria play a key role. The conductivity of copper is approximately twice that of aluminium, and more than three times that of tungsten. The use of copper for fabricating metal interconnects is therefore clearly advantageous for circuits etched with ever increasing fineness.

In addition, copper is also about ten times less sensitive to electromigration than aluminium. This allows its better capacity to maintain the electrical integrity of circuits to be anticipated. Unfortunately, the techniques currently available for fabricating interconnects, particularly copper interconnects, are not sufficiently precise for interconnects below 100 nm and/or incur very high costs.

Although copper is used most in current techniques, the alternative of copper interconnects is faced with two major problems, namely copper is difficult to etch (it is therefore not possible to produce, in a simple fashion, the wiring patterns by processes of this type, albeit conventional processes); and copper is an element with a high rate of diffusion into many materials. This diffusion may lead to the short-circuiting of neighbouring tracks, and therefore to overall malfunction of the circuit.

The use of the damascene process has enabled these two problems to be solved. This process is based on a succession of steps, which are as follows: deposition of an inter-level insulating dielectric layer; etching of the interconnect patterns, consisting of lines and vias, in the dielectric layer by RIE (Reactive Ion Etching); deposition of a barrier layer used to prevent copper migration; filling of the lines and vias with copper; and removal of the excess copper by CMP (Chemical-Mechanical Polishing).

Damascene and dual-damascene processes have been described for example by C. Y. Chang and S. M. Sze in “ULSI Technology”, McGraw-Hill, New York, (1996), pages 444-445. The properties of the barrier layers and their methods of deposition are described by Kaloyeros and Eisenbraun in “Ultrathin diffusion barrier/liner for gigascale copper metallization”, Ann. Rev. Mater. Sci. (2000), 30, 363-85. The method of filling trenches and wells with metallic copper is described by Rosenberg et al., in “Copper metallization for high performance silicon technology”, Ann. Rev. Mater. Sci. (2000), 30, 229-62.

The method of filling with copper used in the damascene process must, from the industrial standpoint, meet certain specifications, as follows: the resistivity of the copper must be as close as possible to the intrinsic resistivity of copper; the copper deposition process must allow complete filling of trenches and wells without creating voids, even—and above all—in the case of etching with high aspect ratios; the adhesion of copper to the barrier layer must be high enough to prevent delamination during the chemical-mechanical polishing step and to allow strong interfaces to be obtained that do not generate fracture zones under electrical or thermal stresses; the cost of the process must be as low as possible. The same applies to the other metals that can be used for the fabrication of interconnects.

To do this, copper deposition using electroplating (EP) offers good performance in terms of quality of the coating deposited, allowing effective filling of the trenches and wells from the bottom up to their opening. This process is based on the galvanic deposition of copper from a bath containing in particular copper sulphate (CuSO₄) and additives. Also known are electroless or autocatalytic chemical plating processes: these are solution processes in which, as in the case of electroplating, the copper coating is obtained by the reduction of cupric ions from an aqueous solution containing them. Unlike electroplating, the electrons needed for this reduction are provided by a chemical reducing agent present in the same solution and not by an external current source, which is why they are called “electroless” plating processes. The solutions used most often are basic aqueous solutions containing a complexed copper salt and formaldehyde (HCHO) as reducing agent, with which the cupric ions are reduced to metallic copper according to a thermodynamically favourable reaction (S. James, H. Cho et al., “Electroless Cu for VLSI”, MRS Bulletin, 20 (1993) 31-38).

These two copper metallic deposition processes are also inexpensive compared with physical and chemical deposition processes, namely PVD (Physical Vapour Deposition) and CVD (Chemical Vapour Deposition) respectively, which are conventionally used for this kind of deposition in the microelectronics industry. These methods use single-substrate vacuum deposition reactors.

However, since electroplating is an electro-mediated reaction, (i.e. the thickness of copper deposited is proportional to the charge passed through the circuit during electrolysis), the topology of the metal coating is sensitive to the cartographical distribution of ohmic drop of the substrate. Now, this distribution is typically very non-uniform in the case of an extended semiconducting surface, like that offered by the barrier layer deposited over the entire substrate wafer used for fabricating the integrated circuit. Since the materials used for the barrier layer (titanium nitride, tantalum nitride, tungsten carbide, etc.) are semiconductors, their conductivity is insufficient to allow uniform copper deposition.

At the same time, the formaldehyde oxidation reaction caused by the copper ions in the electroless process is indeed thermodynamically favourable, but kinetically inoperative without a supply of a catalyst. The most effective catalysts seem to be heterogeneous catalysts, and especially copper. This is because it has been observed that the rate of deposition is considerably increased as soon as a first metallic copper layer becomes available, the process thus being autocatalytic or electroless.

In either case, these problems can be solved by depositing a thin layer of metallic copper, called a seed layer, which in the prior art is only a metal layer, after the step of depositing the barrier layer and before the electroplating step. In the case of electroplating, this copper layer allows a surface of improved and sufficiently uniform conductivity to be covered. In the case of the electroless or auto-catalytic process, it offers an effective catalyst precisely at the point where it is desired to produce the thick copper coating for filling the lines and vias.

The barrier layer and a metal-only seed layer are currently deposited using various processes (PVD and CVD) and in the same vacuum chamber. This avoids having to return to atmosphere between these two steps, and therefore prevents the barrier layer from oxidizing, which would result in a parasitic electrical resistance appearing at the vias.

These process steps, for depositing the barrier layer, for depositing the metal-only seed layer and the copper electroplating, are standard processes at the present time in the microelectronics industry. The three steps require the use of two pieces of equipment, one for the PVD/CVD and the other for the electroplating or for the autocatalytic (electroless) step, which incurs a high cost for implementing these techniques.

A first process of the prior art consists in depositing a copper metal-only seed layer by PVD on the barrier layer without returning to atmosphere after the step of depositing this barrier layer, also by PVD. PVD improves the adhesion of copper to the barrier layer. However, it is observed that copper coatings deposited by PVD exhibit low step coverage when the aspect ratios are high (that is to say the number of recesses and/or etched features is high), which is the case in the production of interconnect lines and vias.

According to a second process of the prior art, the metal-only seed layer is deposited by CVD. The copper films obtained by conventional CVD processes conform better to topology of the surface than those obtained by PVD. However, for most precursors, copper deposited by CVD exhibits poor adhesion to the materials of the barrier layer. In addition, the high cost of CVD precursors makes this process particularly expensive.

As a variant to CVD, the metal-only seed layer of this prior art is deposited by ALD (Atomic Layer Deposition) or ALCVD (Atomic Layer Chemical Vapour Deposition) or ALE (Atomic Layer Epitaxy). This process, considered currently as very promising for ultra-integrated circuits with a very high etching fineness, is based on the same principle as CVD, but using a mixture of gaseous precursors such that the film growth reactions are self-limiting (U.S. Pat. No. 4,038,430 (1977), and M. Ritala and M. Leskela in Handbook of Thin Film Materials, H. S. Nalwa (editor), Academic Press, San Diego, 2001, Volume 1, Chapter 2). ALD therefore operates by a succession of deposition/purge cycles, allowing better control of the thicknesses than in the aforementioned techniques (since the growth rates are typically of the order of 0.1 nm/cycle), and therefore allowing some of the defects of conventional CVD to be corrected, namely good control of the ultra-fine film thickness, moderate modification in the aspect ratio of the etched features, and little dependence on the feed parameters (input flux). This technique has, however, to a lesser extent, some of the defects of conventional CVD, namely poor adhesion and difficulty of obtaining a seed layer having the required properties.

With the reduction in etched feature size, which never stops, the drawbacks of PVD and CVD are increasingly exacerbated, making these processes more and more unsuitable for meeting the challenge of producing seed layers for the etching generations subsequent to the current generations.

Since electroplating and electroless plating result in copper being preferentially deposited on the regions already metallized (either owing to their low resistivity or owing to their catalytic properties), it is necessary for the entire etched feature to receive a coating serving as seed layer, something which PVD seems unable to provide. The appearance of discontinuities and the low conformity to the surface topology are especially problematic at the bottom of wells, trenches and other surface structures of high aspect ratio. When it is applied to a metal-only seed layer obtained by PVD, the deposition of copper by electroplating or by electroless plating therefore becomes increasingly difficult in these regions, as the size of each structure becomes smaller. In addition, in the case of electroless plating, the evolution of hydrogen associated with this process results in micro-porosity and other defects prejudicial to the structure of the material in production phase. Moreover, electroless baths, because of their metastable character, pose stability problems over time.

In conventional CVD processes, a continuous copper film of high conformity can be obtained only above a critical thickness. This is because the copper film has the serious drawback of being discontinuous when it is too thin. The structural integrity of this metal-only seed layer may therefore be affected by the electroplating or electroless plating solution. Now, since the critical thickness is not insignificant compared with the size of the etched features (typically around 30 to 50 nm at the present time, to be compared with etching resolutions that are intended to be below 100 nm), the conformal coating obtained by CVD may result in a significant increase in aspect ratio, and therefore may exacerbate the problems associated with electrochemical filling of the lines and vias from the bottom during the electroplating or electroless plating step. In general, these processes also pose adhesion problems.

At the same time, since ALD is by nature a sequential process based on a succession of cycles, it is slow. Moreover, the mixtures have to be chosen so as to include only gaseous reactants and gaseous products, save one, namely that which it is desired to deposit. The presence of several reactants in the precursor mixture, and of undesirable products on the surface have to be gaseous in order for them to be removed, results in a build-up of constraints, especially technical constraints. The adhesion problems encountered in CVD again occur with this process. In addition, although the thickness control obtained by ALD is of high quality, for certain types of mixtures it is observed that the deposition proceeds by nucleation, which reintroduces the existence of a threshold thickness for obtaining uniform coatings, as described in M. Juppo “Atomic Layer Deposition of Metal and Transition Metal Nitride Thin Films and In Situ Mass Spectrometry Studies”, Academic Dissertation, University of Helsinki, Faculty of Science, Department of Chemistry, Laboratory of Inorganic Chemistry, Helsinki, Finland, Dec. 14th 2001, ISBN 952-10-0221-2, p. 39. These difficulties mean that the candidate chemical structures have to be refined, both as regards the precursors and the coreactants. Thus, ALD is not yet operational and unfortunately does not meet all the current constraints. This also remains an expensive process, both because of the precursors and coreactants and because it is a slow process.

From the problems of the prior art, it may therefore be seen that a real need exists for a process that improves the adhesion of the seed layer to the barrier layer, without sacrificing the formation of a conformal coating, as is the case of PVD. There is also a real need for producing a seed layer on etched features of high aspect ratio using an inexpensive process and providing seed layers that exhibit good adhesion, unlike what CVD can provide. Finally, there is a real need to have a process for producing copper coatings, but also those of other metals, for example such as platinum, in a single piece of equipment, without oxidation of the barrier layer, and at operating temperatures compatible with all of the other materials already present on the substrate.

### SUMMARY OF THE INVENTION

The subject of the present invention is specifically a process which allows all of these requirements to be met, which complies with the aforementioned specifications and which also solves many problems of the prior art that were mentioned above, in particular for the fabrication of metal interconnects, especially for the fabrication of integrated circuits and other Microsystems.

The process of the present invention is a process for coating a surface of a substrate with a seed film of a metallic material, the said surface being an electrically conductive or semiconductive surface and having recesses and/or projections, the said process comprising the following steps:
an organic film is placed on the said surface, the said film adhering to the said surface and having a thickness such that the free face of this film conformally follows the recesses and/or projections of the said electrically conductive or semiconductive surface on which it is placed;
a precursor of the metallic material is inserted within the said organic film placed on the said surface, at the same time as, or after, the step consisting in placing the said organic film on the said surface; and

the said precursor of the metallic material inserted within the said organic film is converted into the said metallic material so that this metallic material forms conformally at the said recesses and/or projections of the said surface to be coated and within the said organic film in order to form, with the latter, the said seed film.

The seed film obtained by the process of the present invention comprises the organic film and the metallic material, these being commingled, with or without chemical bonds or interactions between them, depending on the chemical nature of the materials used.

The inventors firstly observed that the formation of an organic film having the required characteristics—and especially one that conforms to the surface of the substrate—can be produced more easily than a film of metallic material, especially because the spontaneous chemistry of the surface and/or the chemical reactions initiated on the surface for obtaining the organic film allows/allow the geometrical topology of the surface to be respected and partly or completely gets round the problem of the distribution in ohmic drop. Secondly, they noted the property of many organic materials constituting such films of being able to contain and/or support one or more metallic material precursors and to allow these precursors to be converted into the said metallic materials within or on the surface of these organic films. The inventors then very astutely used these observations, combining the use of these organic films with these metallic material precursors, to form, on surfaces, seed films that conform to the recesses and/or projections thereof, even on very small scales, thus solving the many aforementioned problems of the prior art.

Thus, according to the invention, the difficulty of obtaining a seed film by the techniques of the prior art has been reported and solved on the basis of the ability to produce a uniform adherent organic film which conforms to the surface of the substrate, is capable of containing a precursor of the metallic material, and the thickness of which is small enough not to modify the aspect ratio of the surface, for example of the etched features.

The surfaces to which the present invention refers are as numerous as the various possible applications of the present invention. These may be conductive or semiconductive surfaces of three-dimensional objects, or completely or partly semiconductive surfaces. The term “three-dimensional surface” is understood to mean a surface whose topological irregularities are dimensionally not insignificant compared with the thickness of the coating that it is desired to obtain. These are, for example, surfaces of substrates used for the fabrication of Microsystems or integrated circuits, for example silicon substrate (wafer) surfaces and those of other materials known to those skilled in the art in the technical field in question. According to the invention, the substrate may for example be an inter-level layer for the fabrication of an integrated circuit. The present invention is also applicable, for example, in the production of a conducting layer in a MEMS (Micro-ElectroMechanical System) for establishing an electrical contact when two moving parts of the system join up.

The expression “recesses and/or projections” is understood to mean any intentional or unintentional variation in the surface topology. This may for example be a surface roughness due to the substrate or to its fabrication process, surface irregularities, such as scratches, or etched features intentionally produced on the said substrate, for example for the fabrication of Microsystems, integrated circuits and interconnects. The surface having recesses and/or projections may for example be a surface of a microchip.

In general, in the step of the process of the invention that consists in depositing an organic film on the electrically conductive or semiconductive surface, it will be possible to use any process known to those skilled in the art for obtaining an organic film adherent to the surface of the substrate, which conforms to the said surface and has a thickness as defined in the present document. The desired adhesion is that which prevents, as far as possible, the film placed on the surface from debonding during the subsequent steps of the process of the invention. The choice of technique therefore depends on the choice of materials used, especially on the chemical nature of the substrate, on the chemical nature of the surface of the substrate, on the chemical nature of the barrier layer, when this is present, on the polymer chosen for forming the organic film, on the topology of the surface to be coated, and on the intended use of the object manufactured, for example an integrated circuit or the like. This choice also depends on the techniques chosen for the subsequent steps of the process of the invention. Many techniques that can be used in the present invention, and also their characteristics, will be given in the detailed description below.

The term “conformal” is understood to mean one that intimately, i.e. conformally, follows all the asperities of the surfaces, that is to say the entire surface of the recesses and/or projections without filling them or flattening them. Whether or not the recesses and/or projections present on the surface are produced intentionally, that is to say by etching, the process of the present invention allows a metal film to be uniformly and conformally deposited based on the seed film over the entire surface, even within the etched recesses and/or along the projections, as may be seen in the micrographs of FIGS. 20 and 21, and even on very small scales ranging down to 1 nm. The process of the present invention therefore solves the many aforementioned problems of the prior art in which, on these scales, the processes result in coatings which pass over the top of the etched features, without touching the bottom, which fill the recesses and/or projections or which do not operate at all and therefore do not allow such a coating to be produced, or else only at the price of extremely complex and expensive techniques, or else on scales very much greater than 100 nm. The process of the invention also provides metal interconnect dimensions hitherto never achieved.

The technique for placing the organic film on the surface, meeting the aforementioned specifications, may for example be chosen from the following techniques: electro-mediated polymerization, electro-initiated electrografting, spin coating, dipping or spraying. Preferably, when the thickness of the film to be deposited is very small, for example around 1 to 500 nm, and/or when the deposition of this film is sensitive to the cartographic distribution in the ohmic drop of the substrate, the technique used will preferably be an electro-initiated polymerization technique. This is because such a technique allows the problems of ohmic drop to be overcome and makes it possible to obtain a uniform film even at these very small scales. These techniques and their characteristics will be explained below in the detailed description.

Thanks to the aforementioned processes, the thickness of this film may easily lie, without being limited to these dimensions, within a range from 0.001 to 500 μm, for example from 0.001 to 100 μm, for example from 0.001 to 10 μm.

According to the invention, the organic film may be an organic macromolecule or a polymer. Many examples of macromolecules or polymers that may be used will also be given below in the detailed description of the present invention. For example, the organic film may be obtained from a chemical precursor for obtaining this film, the said precursor being chosen from the group consisting of vinyl monomers, methacrylic or acrylic acid ester monomers, functionalized or unfunctionalized diazonium salts, functionalized or unfunctionalized sulphonium salts, functionalized or unfunctionalized phosphonium salts, functionalized or unfunctionalized iodonium salts, precursors for polyamides obtained by polycondensation, cyclic monomers that can be cleaved by nucleophilic or electrophilic attack, and mixtures thereof.

For example, the organic film may be obtained from one or more activated vinyl monomers of the following structure (I): 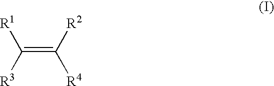
in which R¹, R², R³ and R⁴ are organic groups chosen independently of one another from the group consisting of the following organic functions: hydrogen, hydroxyl, amine, thiol, carboxylic acid, ester, amide, imide, imidoester, acid halide, acid anhydride, nitrile, succinimide, phthalimide, isocyanate, epoxide, siloxane, benzoquinone, benzophenone, carbonyldiimidazole, p-toluenesulphonyl, p-nitrophenyl chloroformate, ethylene, vinyl and aromatic.

According to the invention, the organic film may for example be a polymer obtained by the polymerization of a vinyl monomer chosen from the group consisting of vinyl monomers, such as acrylonitrile, methacrylonitrile, methyl methacrylate, ethyl methacrylate, butyl methacrylate, propyl methacrylate, hydroxyethyl methacrylate, hydroxypropyl methacrylate, glycidyl methacrylate, acrylamides, and especially aminoethyl, aminopropyl, aminobutyl, aminopentyl and aminohexyl methacrylamides, cyanoacrylates, polyethylene glycol dimethacrylate, acrylic acid, methacrylic acid, styrene, p-chlorostyrene, N-vinyl-pyrrolidone, 4-vinylpyridine, vinyl halides, acryloyl chloride, methacryloyl chloride, and derivatives thereof.

According to the invention, the organic film may advantageously include ligand functional groups for precursor metal ions of the metallic material. For example, in the activated vinyl monomer(s) of the aforementioned structure (I), at least one of R¹, R², R³ and R⁴ may be a functional group able to trap the precursor of the metallic material.

When the organic film is placed on the surface of the substrate, the next step of the process of the invention consists in attaching, to the surface of the film and/or in inserting within this film, a precursor of the metallic material.

According to the invention, the expression “precursor of the metallic material” is understood to mean one or more of the aforementioned precursors or a mixture of one or more of the aforementioned precursors. A person skilled in the art will easily be able to select the necessary precursor depending on the seed film that he desires to produce by implementing the process of the invention. Furthermore, this precursor of the metallic material may advantageously be chosen such that it can be converted into the said metallic material by a technique chosen from precipitation, crystallization, crosslinking, aggregation or electroplating. This is because such techniques are particularly practical and effective for implementing the process of the invention.

For example, according to the invention, the precursor of the metallic material may be an ion of the metallic material. For example, it may be chosen from the group consisting of copper ions, zinc ions, gold ions and ions of tin, titanium, vanadium, chromium, iron, cobalt, lithium, sodium, aluminium, magnesium, potassium, rubidium, caesium, strontium, yttrium, niobium, molybdenum, ruthenium, rhodium, palladium, silver, cadmium, indium, lutetium, hafnium, tantalum, tungsten, rhenium, osmium, iridium, platinum, mercury, thallium, lead, bismuth, lanthanides and actinides. In certain cases it may also be advantageous to use mixtures of ions, which for example may be chosen from the above list.

According to the invention, for example for fabricating interconnects for microsystems, for example integrated circuits, the metallic material may advantageously be copper, palladium or platinum and the precursor may be copper ions, palladium ions or platinum ions respectively.

According to the invention, the precursor may be in the form of metal particles or aggregates, optionally encapsulated in a protective gangue, chosen from the group consisting of micelles, polymer nanospheres, fullerenes, carbon nanotubes, cyclodextrins, and in which the step of converting the precursor into the said metallic material is carried out by releasing the metal particles or aggregates from their gangue.

The attachment of the precursor of the metallic material onto, or the insertion into, the organic film may be carried out by means of any suitable technique depending on the chemical nature of the film and of the precursor of the metallic material. The techniques that can be used within the context of the present invention for this step are therefore numerous—they range from simply bringing the precursor of the metallic material into contact with the organic film placed on the surface, for example by dipping the organic film deposited on the surface of the substrate into a suitable solution of the said precursor (i.e. dip coating), for example of the type of those used in the prior art for electroplating, to more elaborate techniques, such as the use of an electrolytic bath or spin coating, on the said surface.

One or other of the aforementioned means of implementation is thus used to obtain an ultrathin film of precursor of the metallic material, which is adherent, uniform and in particular conformal. This is because, unlike all the processes of the prior art, the process according to the invention enables the precursor of the metallic material to be forcibly located near the surface of the barrier layer, within the organic film conforming to the recesses and/or projections. In addition, thanks to the process of the invention, the thickness of the metallic material precursor layer onto the surface of the substrate, and where appropriate the thickness of the barrier layer, may be adjusted by adjusting the thickness of the organic film placed on the said surface and used as support or matrix for the trapping of the precursor of the metallic material, and/or by adjusting the penetration of the metallic precursor into the said organic film.

If the organic film does not allow easy insertion of the precursor of the metallic material into it, or if this insertion has to be promoted, or even forced, according to the invention it is advantageously possible to use an insertion solution that is both a solvent for or transporter of the precursor of the metallic material, and a solvent and/or a solution that swells the organic film, the said insertion solution including the precursor of the metallic material. The expression “solution that swells the organic film” is understood to mean a solution that is inserted into this film and that opens out its structure in order to allow the insertion within it of the precursor of the metallic material. For example, this may be an aqueous solution, for example one that hydrates the organic film. Thus, certain vinyl polymers are swelled by water, especially poly(4-vinylpyridine) or P4VP, which is not soluble in water, or else poly(hydroxyethyl methacrylate) or PHEMA, which is soluble in water and is therefore also swollen by this solvent. For example, an aqueous solution can be used with an organic film consisting of a vinyl polymer and a precursor of the metallic material, such as copper.

This insertion solution is also a solution that allows the precursor of the metallic material to be conveyed into the organic film. It will therefore be a solution that allows the precursor to be sufficiently dissolved or dispersed for the present invention to be implemented. This is because, in the case of insoluble salts of the precursor of the metallic material, this solution must preferably be able to disperse the precursor of the metallic material sufficiently to be able to allow this precursor to be inserted into the organic film. The choice of insertion solution will therefore depend on many criteria. Among these, mention may be made of the following: that depending on the surface, for example in order to avoid chemical interactions such as oxidation of the surface during implementation of the process; that depending on the organic film, so that this solution does not withdraw the film from the surface on which it has been deposited; that depending on the precursor of the metallic material—it must allow it to be dissolved but also to be converted into the metallic material; and that depending on the metallic material—it must allow it to be formed within the organic film, and especially it must allow its deposition process to be carried out, for example the electroplating of the metallic material or its electroless plating.

For example, since there is extensive prior art, on the one hand, on how to obtain metal films by electroplating from aqueous solutions and, on the other hand, on their water-solubility properties, the preferred appropriate insertion solution according to the invention is an aqueous solution of this type, especially when the organic film is a polymer that can be swelled by water, for example in the form of an electrografted reinforcing film. Other insertion solutions and methods of inserting the precursor of the metallic material within the organic film will be described below. A person skilled in the art will know how to choose other suitable solvents.

According to a first particular method of implementing the present invention, the step consisting in inserting the precursor of the metallic material into the organic film placed on the said surface may be carried out at the same time as the step consisting in placing the organic film on the said surface by means of an insertion solution comprising both the said organic film, or a precursor of the said organic film, and the precursor of the metallic material. This method of implementation is shown schematically in FIG. 3 appended hereto. This method of implementation is particularly advantageous, for example when it is difficult to find an effective insertion solution for inserting the precursor of the metallic material into the organic film based on the substrate. Thus, during the first step consisting in placing the organic film (OF) on the substrate, the precursor of the metallic material (pM) is held within the organic film (OF) and, when the film has been placed on the surface (S), it is possible to apply that step of the process of the invention which consists in converting the precursor of the metallic material into the said metallic material within the said organic film in order to form the seed film (SF).

The step of inserting the precursor of the metallic material into the organic film may be followed by suitable rinsing in order to remove the excess precursor and thus improve its confinement in the organic film. Thus, in certain cases the uniformity of the seed film obtained after conversion of the precursor may be improved.

Once the precursor of the metallic material has been attached and/or inserted into the organic film, the said precursor may then be converted into the said metallic material, for example by reduction, on or in the organic film. Thus, when the precursor is a metal ion, it is reduced to the said metal, for example by a galvanic-type process, such as electroplating or ECD (electrochemical deposition), or by electroless plating. In the case of encapsulated metal particles or aggregates, the reduction may pertain to the encapsulating molecules. This is because it is easy to synthesize metal aggregates (of Au, Cu, Ni, Fe, etc.) ranging in size from a few nanometres to a few tens of nanometres for example by reduction of a solution of ionic precursors of these metals in a two-phase medium or a medium containing inverse micelles, as indicated for example by M. Brust, M. Walker, D. Bethell, D. J. Schiffrin and R. Whyman in “Synthesis of thiol-derivatized gold nanoparticles in a two-phase liquid-liquid system”, Journal of Electrochemical Society, Chemical Communications, 801 (1994). Such aggregates are widely used as markers in the field of biochemistry or molecular biology, as they prove to be fluorescent. They are therefore readily available commercially as aqueous dispersions or else dispersions coupled with proteins, polysaccharides, oligonucleotides, etc. Likewise, it is known to imprison nanoscale metal aggregates in nanoscale objects such as fullerenes or carbon nanotubes. Metal aggregates (that is to say in the zero oxidation state) encapsulated in an organic gangue, for example surfactants and/or thiols, which stabilize them, are obtained. The gangue may be detached from the aggregates by electroreduction, causing them to coalesce and resulting in metal particles or even in the precipitation of a metal on the surface. In certain cases, the same result requires an oxidation reaction, depending on the chemical nature of the material constituting the gangue of the aggregates and in particular on the nature of their bonds with these aggregates.

Whatever the precursors, it is therefore possible to reduce those that were previously confined in the organic film, either at the time of manufacture of this organic film on the surface or subsequently, by inserting and/or depositing these precursors, for example by dipping the attaching film and/or simple diffusion of the precursors within it, or else due to the effect of various stimuli, such as by electron withdrawal so as to force or promote the attachment and/or insertion of the precursor into the film, etc.

If the objective of implementing the process of the invention is simply to produce a seed layer, a single step of inserting the precursor of the metallic material into the film and of converting this precursor may suffice. The recesses may then be filled in if such is the objective of implementing the process of the invention, starting from the seed layer thus created, using the processes of the prior art, preferably electroplating or electroless plating.

According to a second particular method of implementing the present invention, the step of attaching or inserting the precursor of the metallic material into the organic film may be carried out by means of a first solution containing the precursor of the metallic material, and the step of converting the metal precursor into the said metallic material within the organic film is carried out by means of a second solution that does not contain the said precursor of the metallic material. Thus, an organic film is produced on the surface to be coated, and then this surface is dipped into two different baths. By dipping it into a first bath containing the precursors of the metallic material, it is possible to fill and/or cover the film with precursors (by inserting and/or attachment). The surface is then removed from the first, “filling” (and/or “attachment”) bath, possibly rinsed and then immersed in a second solution containing various chemical agents, with the exception of the precursors of the metallic material of the previous bath. These chemical agents may be oxidation-reduction agents, for example for an electroless-type process for reducing the precursor of the metallic material, or electrolytes in order to ensure electrical conduction in an electroplating-type production process. When the reduction takes place in this second bath, the ions contained on and/or in the film constitute the sole “reservoir” of precursors available to the reaction in order to form the metallic film, since they are absent in the bath. Providing that the organic film is uniform—and especially conformal—it is thus possible to confine the electroplating reaction in a uniform space, and especially one that is conformal with the surface.

Proceeding in this manner avoids having to reprovision with metallization precursors from the solution, especially in the most conducting regions, if they exist, and overcomes any electroplating or electroless plating irregularities in this step of producing the seed layer—the construction of the metal film (by reduction) is promoted at the place where the precursors have been trapped, thanks to the organic film, and only at this point, that is to say on or in a uniform ultrathin film conformal with the surface structure of the barrier layer.

When the film is covered and/or filled with the precursors of the metallic material on leaving the first bath, the concentration gradients between the film (filled with precursors) and the solution of the second bath (containing no precursors) are favourable to the release of the precursors into the optional rinsing bath and in particular into the second dipping bath. Admittedly, this release may be prevented by resolutely trapping the precursors on and/or in the organic film (via a complexation when ions are inserted, or else via chemical coupling and/or crosslinking in the case of aggregates). However, normally it is observed that the use, in the second bath, of a liquid that is not a solvent nor even a good swelling agent for the organic film, may be sufficient in order to prevent this release. More generally, any operating improvement that will make the rate of release slow compared with the rate of deposition of the metal in the film from the precursors will be acceptable and in accordance with the scope of the present invention.

If the objective of implementing the process of the invention is to carry out very gradual, uniform and conformal filling, the number of successive passes into the above two baths may be increased so as, admittedly, to reprovision the film with precursors, but again to be able to ensure that this reprovisioning is limited spatially to the thickness of the film, the “roots” of which are increasingly buried as the passes into a solution or bath for inserting the precursor of the metallic material and then into the deposition bath succeed one another. Thus, according to the invention, the steps of inserting the precursor of the metallic material into the organic film and of converting the said precursor into the said metallic material may be alternately repeated several times.

According to the invention, the substrate may include, on its electrically conductive and/or semiconductive surface having recesses and/or projections, a barrier layer that prevents the metallic material from migrating into the said substrate, the said barrier layer having a thickness such that the free face of this layer conformally follows the recesses and/or projections of the said substrate on which the said barrier layer is deposited. The function of this barrier layer was explained above in the prior art part—it prevents the metallic material from migrating into the substrate. This is therefore valid for certain substrates and with certain metallic materials, for example a silicon substrate and a copper-based metallic material.

According to the invention, before the step consisting in placing the organic film on the said surface of the substrate, the process of the invention may furthermore include a step that consists in depositing the said barrier layer. This deposition may be carried out by one of the techniques known to those skilled in the art, for example the technique described in the Kaloyeros and Eisenbraun document “Ultrathin diffusion barrier/liner for gigascale copper metallization” in Ann. Rev. Mater. Sci. (2000), 30, 363-85.

According to the invention, the materials used for producing the barrier layers, for example in the field of copper interconnection, for example in micro-electronics, are generally semiconductors. They may be materials used in the prior art. For example, the barrier layer may be a layer of a material chosen from the group consisting of the following: titanium; tantalum; titanium, tantalum and tungsten nitrides; titanium and tungsten carbides; tantalum, tungsten and chromium carbonitrides; silicon-doped titanium or tantalum nitride; and ternary alloys comprising cobalt or nickel alloyed with a refractory such as molybdenum, rhenium or tungsten, and with a dopant such as phosphorus or boron. For example, the barrier layer may be a layer of TiN or TiN(Si) and the metallic material may be copper.

According to the invention, the barrier layer may be deposited on the substrate by one of the aforementioned techniques of the prior art, for example by a technique chosen from the group consisting of chemical vapour or physical vapour deposition techniques. One of these techniques is for example described in the aforementioned document.

For the aforementioned application to metallic interconnects in microelectronics, for example copper interconnects, the seed layer appears to be the most problematic in the techniques of the prior art on etching generations of 0.1 μm and below. The process of the present invention readily makes it possible to obtain seed films having a thickness “h” within the 1 to 100 nm range, and even the 1 to 50 nm range, depending on the size of the recesses and/or projections to be coated (FIG. 1(a) and FIG. 4). More generally, the required thicknesses for fabricating microsystems may be from 1 nm to 100 μm for example, and more particularly from 500 nm to 5 μm. These thicknesses may be readily obtained using the process of the present invention. Similarly, the thicknesses required for making connections may be more intentionally between 1 and 500 μm, and more particularly between 1 and 10 μm. Again, these may be readily obtained by the process of the present invention.

The present invention also relates to a process for fabricating interconnects in microelectronics, using the aforementioned process, the said inter-connects consisting of a metallic material. The inter-connect fabrication process of the invention may include, in the following order, the steps consisting in:

a) etching interconnect patterns in a dielectric substrate, the said patterns forming recesses and optionally projections on and/or through the said substrate;

b) depositing a conducting barrier layer on the said etched dielectric substrate, which layer prevents the metallic interconnect material from migrating into the said substrate, the said barrier layer having a thickness such that the free face of this layer conformally follows the interconnect patterns of the said substrate on which the said layer is deposited;

c) coating the conducting barrier layer deposited on the etched substrate with a seed film of a metallic material by means of the aforementioned coating process of the invention; and

d) filling the recesses with the said metallic material starting from the said seed film in order to form the said metal interconnects made of the said metallic material.

The substrate, steps b) and c), and the materials that can be used in this process were explained above.

The etching step may be carried out by the usual microetching or nanoetching techniques for etching substrates, and even, because of the access of the process of the invention to scales ranging down to 1 nm, by the techniques known to those skilled in the art for obtaining such etched features. For example, reactive ion etching techniques may be used to implement the process of the invention.

According to the invention, the step of filling the recesses in the interconnect fabrication process may be carried out by any technique known to those skilled in the art for filling an etched feature with a metal in the fabrication of Microsystems and integrated circuits, for example the techniques of electroplating of metallic materials or of electroless plating starting from the seed layer. Preferably, to solve the aforementioned ohmic drop problems, and thanks to the process of the invention, the filling step may be carried out by means of an electroless technique using a solution of a precursor of the metallic material. Techniques that can be used for this plating are described by C. Y. Chang and S. M. Sze in the document “ULSI Technology” McGraw-Hill, New York, (1996), pages 444-445.

According to the invention, the process may furthermore include, after the step for filling the recesses with the metallic material, a step of polishing the excess metallic material found on the said surface. This step may be carried out by means of conventional processes used for the fabrication of microsystems, for example CMP (chemical-mechanical polishing). One of these techniques is described in the aforementioned process.

The present invention also relates to a process for galvanically plating a surface, the said surface being an electrically conductive or semiconductive surface and having recesses and/or projections, which process may comprise the following steps:
coating of the said surface with a seed film of a metallic material using the process for coating a surface with a seed film according to the present invention; and
galvanic deposition of a metal layer of the said metallic material starting from the said seed film obtained.

The aforementioned galvanic deposition step may be carried out in the same way as the aforementioned filling step. The other materials and techniques of this process are those described above. The galvanic coating obtained has the characteristics of being conformal to the surface on which it is deposited, even on a nanoscale, on surfaces that include recesses and/or projections.

### DETAILED DESCRIPTION OF THE INVENTION AND PARTICULAR EMBODIMENTS OF THE INVENTION

The process of the present invention is based on the production of an organic film adheres to the surface of a conductive or semiconductive substrate, for example by chemical or electrochemical reactions, so as to protect thereon and/or support thereon and allow thereon the growth of a metal coating starting from a precursor, in order to obtain a seed film conformal to the said surface and to solve the aforementioned drawbacks of the prior art. More precisely, the process of the invention allows an adherent and preferably uniform organic film to be constructed on the surface of a conductive or semiconductive substrate, the said film being conformal as shown in FIG. 1a appended hereto. The notion of conformality is essentially tied to the characteristic size of the topological irregularities on the surface or of the intentional etched features of the said surface. In the general case, it may be considered that the film is conformal to the surface if it preserves, at any point on the surface and to within a certain tolerance, the local radius of curvature present before the film has been deposited.

In the microelectronics case, the process of the invention makes it possible to produce a metal seed layer thanks to a succession of chemical or electro-chemical steps directly on the surface of the substrate when this is possible, or on the barrier layer when the latter is necessary. In the case of galvanic deposition on a macroscopic component, the process of the invention makes it possible to produce a layer whose thickness is of the same order of magnitude as the smallest radius of curvature of any of the parts of the surface of the component in question, including in the recesses and/or projections of the said surface. This metal layer conformal to the surface is obtained thanks to the seed film obtained by the process of the present invention.

FIG. 1 is a schematic representation of the process of the invention, diagrams a) to c) showing the fabrication of a seed film (SF) and diagram d) showing the filling of a recess with a metallic material (MM) starting from the seed film (SF).

Diagram a) shows the deposition of an organic film (OF) on the surface of a substrate (S) having a recess (R). A barrier layer (BL) is also shown in this diagram, although its presence is not always necessary.

When the process of the invention is applied for example in microelectronics, the thickness has to be small enough not to increase the aspect ratios (FIG. 1a) and not to handicap the following steps of forming the seed film and, where appropriate, of filling the recess (FIGS. 1b, 1c and, where appropriate, FIG. 1d). The process of the invention therefore preferably uses processes for depositing an organic film that make it possible to obtain thicknesses substantially less than d, where d is the width of the etched feature, and more particularly less than d/2. For 0.1 μm etching, the thickness of the layer will be for example between 1 and 100 nm, and more particularly between 1 and 50 nm. It is sufficiently uniform, that is to say the small thickness, as datum, has to be ensured, to within a tolerance value deemed acceptable, over the entire coated surface of the substrate. It is preferably conformal to the topological structuration of the surface of the substrate, this preferably being in fact a consequence of the above two aspects.

The force required to make the organic film adhere to or be fixed on the surface is essentially determined by the steps that follow its formation. If for example the precursors are inserted by dipping into a solution of the type of those used for electroplating, preference is advantageously given to methods for fixing the organic film which will give a coating that will not be washed off by these solutions, for example by not being soluble therein, or else by being firmly attached to the surface via physico-chemical bonds, such as the grafting as shown in FIGS. 2 and 4. Preferably, the methods capable of promoting the formation of bonds at the substrate surface interface or the barrier layer/organic film interface, and preferably covalent, ionic or dative chemical bonds, corresponding to Lewis acid-based interactions. However, as will be seen in the exemplary embodiments, it may also be desired to obtain an adherent metal layer, for example on the surface of a semiconductor, by carrying out the reduction of the precursors within an organic layer simply deposited on the surface, as shown in FIG. 3 appended hereto. This may be achieved, for example by depositing an organic film (OF) already filled with the precursors (pM) (FIG. 3a). This thus avoids a specific filling, i.e. insertion, step which necessarily has to include the use of a solvent or a swelling agent for the polymer, liable to result in the surface being washed. Here, the step consisting in placing the organic film on the surface and the step of inserting the precursor of the metallic material of the process of the invention are carried out simultaneously. The precursor of the metallic material is then converted into the said is metallic material within the organic film (FIG. 3b) in order to obtain the seed film (SF) according to the present invention.

The organic film may for example be based on the surface of the substrate by spin coating, or by dip coating or by spraying, using a solution containing the molecules or macromolecules that will serve to form the organic film in the following two cases (i) and (ii):

(i) when the dry residue formed by these molecules or macromolecules is insoluble in the formulations used in the following steps of the process of the invention, and especially in those for the electroplating or electroless plating intended for converting the precursor of the metallic material into the said metallic material. This may for example be achieved with polymers that can crosslink after deposition, either through the external action of a specific crosslinking agent, or thanks to them being compounded (blended) with crosslinking agents, or by both of these means. These polymers or their polymer precursors are therefore soluble in their deposition solvent, because they are not crosslinked. Once the solution has been deposited, it is possible to carry out the polymerization and the crosslinking on the surface when the bath contains the precursors of these polymers. In the case in which the solution contains a polymer that is already formed, it is possible to cure it, or to irradiate it, for example with photons, electrons, ions, etc., or else to apply any form of suitable stimulus, such as a change in pH, temperature, etc. to these polymers, so as to cause them to crosslink. In particular, this crosslinking makes them insoluble in the solvent used for depositing them and in many other solvents, even for low degrees of crosslinking. For example, the following can be used according to the invention: vinyl polymers, and especially poly(methyl methacrylate) (PMMA) and other polymers whose monomers are based on esters of methacrylic acid or acrylic acid, such as poly(hydroxyethyl methacrylate) (PHEMA), polycyanoacrylates, polyacryl-amides, poly(4-vinylpyridine), poly(2-vinylpyridine), polyvinylcarbazole; polymers obtained by poly-condensation such as polyamides and especially nylons, polysiloxanes and polyaminosiloxanes; polymers obtained from cyclic monomers that can be cleaved by nucleophilic or electrophilic attack, and especially lactides, epoxies, oxiranes, lactams, lactones, and especially ε-caprolactone; non-polymeric macromolecules, such as cellulose and its derivatives and especially hydroxypropylmethyl cellulose, dextrans, chitosans, whether functionalized or not. These macromolecules can either be crosslinked directly, without an additional crosslinking agent, or can be crosslinked via the introduction of a crosslinking agent. These agents, present in the formulation, are the ones known to those skilled in the art. Mention may especially be made of molecules carrying at least two functional groups compatible with the functional groups of the polymer or created on the polymer by an external action, for example by a change in pH, by heat, by irradiation, etc. These may for example be molecules chosen from the group consisting of: divinylbenzene or pentaerythritol tetramethacrylate; diamines such as, for example, hexamethylenediamine; epichlorohydrin; glutaric anhydride; glutaraldehyde; bis-epoxides; dicarboxylic acids such as azelaic acid; bis-siloxanes; aminosiloxanes, such as γ-aminopropyltriethoxysilane (γ-APS); bis-chlorosilanes, bis-isocyanates, etc. Preferably, the molecules or macromolecules used in the formulation may advantageously bear, in addition to their intrinsic functional groups, complementary functional groups, and especially functional groups that may serve as ligands for ions, and especially metallization precursor metal ions. Among these functional groups intrinsically or additionally present on the macromolecules of the organic film, mention may especially be made of amines, amides, ethers, carbonyls, carboxyls and carboxylates, phosphines, phosphine oxides, thioethers, disulphides, ureas, crown ethers, aza-crown compounds, thio-crown compounds, cryptands, sepulcrands, podands, porphyrins, calixarenes, pyridines, bipyridines, terpyridines, quinolines, orthophenanthroline compounds, naphthols, iso-naphthols, thioureas, siderophores, antibiotics, ethylene glycol, cyclodextrins, and substituted and/or functionalized molecular structures based on these functional groups;

(ii) when the molecules and macromolecules of the formulation bear specific functional groups, which may form bonds with the surface of the barrier layer spontaneously when these groups come into contact with the surface of the barrier layer. These molecules, having a generic structure that may be written as A-B, consist of a reactive end group B, capable of being spontaneously fixed onto the surface of the barrier layer, by this layer coming into contact with a liquid phase containing the A-B molecules or their organic precursors, and of a body A bearing various reactive groups, especially the ligands for the metallization precursor cations. For example, mention may be made of diazonium salts of formula {R-Φ-N₂⁺, X⁻}, in which A=R and B=Φ. This is because it is known that diazonium salts can be cleaved at room temperature to give an aromatic radical R=Φ* can be fixed onto the surface. In the above formula: Φis an aromatic ring; X⁻ is an anion chosen especially from the group consisting of tetrafluoroborates, halides, sulphates, phosphates, carboxylates, perchlorates, hexafluorophosphates, ferrocyanides and ferricyanides; and R is any, linear or non-linear, branched or non-branched organic group, optionally of macromolecular nature, comprising Lewis-type basic functional groups capable of forming ligands for the Lewis acids, and especially the metallization precursor cations. Among these functional groups, mention may especially be made of amines, amides, ethers, carbonyls, carboxyls and carboxylates, phosphines, phosphine oxides, thioethers, disulphides, ureas, crown ethers, aza-crown compounds, thio-crown compounds, cryptands, sepulcrands, podands, porphyrins, calixarenes, pyridines, bipyridines, terpyridines, quinolines, orthophenanthroline compounds, naphthols, iso-naphthols, thioureas, siderophores, antibiotics, ethylene glycol, cyclodextrins, and substituted and/or functionalized molecular structures based on these functional groups. The R group may especially be any one of the macromolecules mentioned in the list of case (i) above. Among the molecules that can be spontaneously adsorbed on the surface, for example by thermal activation, mention may also be made of molecules substituted with thermal or photochemical precursors, by the formation of radicals, such as for example radical polymerization initiators such as nitroxides, for example 2,2,6,6-tetramethyl-piperidinyloxy (TEMPO); alkoxyamines; substituted triphenyls; verdazyl derivatives; thiazolinyl; peroxides, such as for example benzoyl peroxide; thioesters; dithioesters; and disulphides.

The spin coating process, sometimes called the spin-on process in microelectronics, is in fact a process that allows very thin organic films to be deposited, even though it is particularly effective on surfaces that are not rough, given that the uniformity of the films obtained is optimum when the flow of the fluid is laminar, which may sometimes not be the case (“Eckman's spirals”) plumb with surface irregularities. In addition, it has been observed that, for ultrathin films, the evaporation of the solvent during application of the process increases, sometimes locally inhomogeneously, the viscosity of the fluid and results in a non-uniform thickness. Specific devices that can be used in the present invention, which require the saturation vapour pressure, temperature and even humidity to be controlled, are described for example in U.S. Pat. No. 5,954,878 (1997) and U.S. Pat. No. 6,238,735 (1999). According to a variant, other processes that can be used according to the invention are processes for the solvent annealing of organic coatings deposited by spin coating, which processes are described for example in U.S. Pat. No. 6,312,971 (2000). Like the reactive thermal annealing carried out on hybrid films (U.S. Pat. No. 5,998,522 (1998)) that can also be used in the present invention, these processes require a step additional to the simple deposition, in order to obtain a uniform layer, namely the annealing step.

Since the substrate according to the invention is preferably electrically conductive or semiconductive, according to the invention the organic film may also be placed on the surface using the entire panoply of growth and/or grafting reactions for electrochemically initiated organic films. However, as was seen earlier, the reactions that can be used are preferably those that make it possible to produce films of uniform thickness and conformal to the said surface, whatever the geometric topology of the surface. As previously, it is therefore preferable to select electrochemical reactions that are somewhat insensitive to the surface electric field topology. In general, electro-initiated reactions meet this constraint, and are therefore reactions that can be used for forming the organic film that is intended to be contained during the following steps of the process of the invention, namely the reduction of the precursors of the metallic material in order to obtain the seed layer. The term “electro-initiated reactions” is under-stood to mean electrochemical reactions that include at least one step of charge transfer with the working surface coupled, before or afterwards, with chemical reactions one of which is a reaction involving charge transfer with the same working surface. For example, these may be the following reactions:
polymer electrografting reactions: the electrografting of polymers makes it possible to initiate the growth of polymer chains thanks to an electrically biased metal surface, which serves as initiator. Whether these be cathodic or anodic electro-grafting reactions for the electrografting of vinyl precursors or of cyclic precursors that can be cleaved by nucleophilic or electrophilic attack, as described for example in EP 038 244 or in EP 665 275, or else anodic electrografting reactions for the electro-grafting of functionalized alkynes onto silicon surfaces, as described for example by E. G. Robins, M. P. Stewart and J. M. Buriak in “Anodic and cathodic electrografting of alkynes on porous silicon”, Chemical Communications, 2479 (1999), polymer chains are obtained by purely chemical growth (propagation reactions) driven by this initiation: a single charge transfer reaction therefore gives rise to a complete chain, the growth of which involves no additional charge transfer reaction. Experience acquired in the field shows that the thickness range of between 2 nm and 1 μm is achievable with this type of process. One of the particular aspects of polymer electrografting is that it results in the formation of truly covalent carbon/surface bonds between the polymer and the surface (FIG. 2). The precursor monomers for the vinyl polymer electrografting reactions that can be used according to the invention are, for example, monomers containing activated vinyl groups, that is to say those carrying electron-withdrawing or electron-donating substituents, and/or rings that can be opened by nucleophilic or electrophilic attack, these optionally being activated. Mention may especially be made of the following: acrylonitrile; methacrylonitrile; substituted methacrylates, and especially methyl methacrylate, ethyl methacrylate, butyl methacrylate, propyl methacrylate, hydroxyethyl methacrylate, hydroxypropyl methacrylate and glycidyl methacrylate; acrylamides, and especially aminoethyl, aminopropyl, aminobutyl, aminopentyl and aminohexyl methacrylamides; cyanoacrylates and cyanomethacrylates; polyethylene glycol dimethacrylate; and more generally telechelic diacrylates or dimethacrylates, and also macromolecules carrying acrylate or methacrylate groups and more generally activated vinyl groups; acrylic acid and methacrylic acid; styrene, p-chlorostyrene and more generally activated substituted styrenes; N-vinyl-pyrrolidone; 4-vinylpyridine and 2-vinylpyridine; vinyl halides; acryloyl chloride and methacryloyl chloride; divinylbenzene (DVB); pentaerythritol tetramethacrylate; and more generally acrylate-, methacrylate- or vinyl-based crosslinking agents, and derivatives thereof. Especially useable for forming electrografted films are solutions comprising one of the compounds of the above list or a mixture of several of those compounds, thereby making it possible to envisage the formation of crosslinked copolymers and/or networks. Among the compounds having rings opened by nucleophilic or electrophilic attack can be used, in particular, epoxides, oxiranes, lactones, and especially capro-lactones, lactams, and also any molecule or macro-molecule carrying such groups. Functionalized alkynes that can be used in the present invention, for example for anodic electrografting onto a silicon surface, are for example compounds of the generic formula R—C≡C—H, where R is any organic group whatsoever, whether linear or not, branched or not, optionally of macromolecular nature, which includes Lewis-type basic functional groups capable of constituting ligands for the Lewis acids, and especially the metallization precursor cations. Among these functional groups, mention may especially be made of amines, amides, ethers, carbonyls, carboxyls and carboxylates, phosphines, phosphine oxides, thioethers, disulphides, ureas, crown ethers, aza-crown compounds, thio-crown compounds, cryptands, sepulcrands, podands, porphyrins, calixarenes, pyridines, bipyridines, terpyridines, quinolines, orthophenanthroline compounds, naphthols, iso-naphthols, thioureas, siderophores, antibiotics, ethylene glycol, cyclodextrins, and substituted and/or functionalized molecular structures based on these functional groups. The R group may have a molecular structure of arbitrary size, especially any macro-molecule and in particular a polymer;
electrografting reactions for grafting organic fragments by electrocleaving reactions: these are in fact the particular case of electroinitiated reactions in which the charge-transfer-coupled reactions are the cleaving of the electroreduced or electrooxidized molecule (homolytic or heterolytic cleavage) and the adsorption of at least one of the two cleaved species onto the working surface. Especially useable reactions in this category are reactions involving the electroreduction or electrooxidation of diazonium salts, such as those reactions described in WO 98/44172, of sulphonium salts, such as those described in U.S. Pat. No. 6,238,541, of phosphonium and iodonium salts, of peroxodisulphates, persulphates, thio-sulphates, ferrocene, carboxylic acids and especially benzoic acids, for example by the Kolbe reaction described in WO 98/40450, or of peracids, and also, in particular, onto silicon surfaces, reactions for the cathodic electrografting of alkynes, such as those described by E. G. Robins, M. P. Stewart and J. M. Buriak in “Anodic and cathodic electrografting of alkynes on porous silicon”, Chemical Communications, 2479 (1999), op. cit. These reactions are used to firmly fix ultra-thin organic layers to any electrically conductive or semiconductive substrate, with the formation of covalent interfacial bonds, by prefunctionalizing the precursor with the functional groups of interest that it is desired to fix onto the surface. Within the context of the present invention, it is possible to use, for example, diazonium salts of formula {R-Φ-N₂⁺, X⁻} in order to obtain, by electroreduction, the grafting of R-Φ- fragments onto the working surface. In the above formula: 4) is an aromatic ring; X⁻ is an anion and especially a tetrafluoroborate, a halide, a sulphate, a phosphate, a carboxylate, a perchlorate, a hexafluorophosphate, a ferrocyanide or a ferricyanide; and R is any linear or non-linear, branched or unbranched, organic group, optionally of macromolecular nature, which includes Lewis-type basic functional groups capable of constituting ligands for the Lewis acids, and especially the metallization precursor cations. Among these functional groups, mention may especially be made of amines, amides, ethers, carbonyls, carboxyls and carboxylates, phosphines, phosphine oxides, thioethers, disulphides, ureas, crown ethers, aza-crown compounds, thio-crown compounds, cryptands, sepulcrands, podands, porphyrins, calixarenes, pyridines, bipyridines, terpyridines, quinolines, orthophenanthroline compounds, naphthols, iso-naphthols, thioureas, siderophores, antibiotics, ethylene glycol, cyclodextrins, and substituted and/or functionalized molecular structures based on these functional groups. The R group may be a molecular structure of arbitrary size, and especially any macro-molecule, and in particular a polymer. It is also possible in particular to use an alternative approach to that described in the preceding paragraph in order to graft polymers onto surfaces, namely, instead of constructing the polymer block by block on the surface, by direct initiation (electrografting of polymers), it is possible to consider a polymer already formed that is functionalized with aromatic amine groups (-Φ-NH₂), which are then converted into diazonium salts by a suitable procedure known to those skilled in the art, such as a reaction with HCl/NaNO₂ or with NOBF₄, before a cathodic potential is applied for grafting these groups—and therefore grafting the polymer to which they are attached—onto the said surface. Such a polymer may especially be chosen, as indicated above, for its property of capturing the precursor ions of the metal film. Similarly, it will be possible to make use of alkynes, of general formula R—C≡C—H, in which the R group is also any group having the same characteristics as above;
electro-initiated electropolymerization reactions: these are reactions in which a mixture is used that comprises at least one electrically actuable initiator, preferably a radical initiator, and at least one polymerizable monomer. The mixtures may for example be those containing the compounds described above, namely comprising at least one diazonium salt and at least one vinyl monomer. The cathodic biasing of a surface in such a mixture results in the electro-reduction of the diazonium salt and in the formation of R-Φ* radicals, which can initiate the radical polymerization of the vinyl monomer. As may be seen, only the initiation step uses a charge transfer reaction, whereas the formation of the polymer film proceeds by purely chemical steps—these are therefore indeed electro-initiated reactions within the meaning of the invention.

The electro-initiated reactions considered here have the particular feature that only the initiation step involves the consumption or generation of an electrical current. In each of the above mentioned electro-initiated reactions, the current serves essentially to increase the density of grafts per unit area (since each charge transfer reaction is associated with the formation of an interfacial bond), whereas the growth of the organic film—when this takes place (such as for example in the case of the electrografting of vinyl polymers)—is controlled only by chemical reactions. The maximum number of grafted chains per unit area is equal to the number of sites per unit area (about 10¹⁵ sites/cm²) with which it is possible to form a carbon/metal interfacial bond. If the maximum degree of coverage—whatever it is—can be obtained, for example for a fixed potential, by biasing for about 1 minute, it may be deduced therefrom that the electrical currents involved are of the order of ten to one hundred microamps per cm² of actual surface, irrespective of the type of electro-initiated reaction in question. As will be seen in the exemplary embodiments, this order of magnitude proves to be quite correct in most cases, for identical surface roughnesses. These currents are therefore two to three orders of magnitude less, for comparable thickness, than those that may be encountered in electro-mediated reactions (electrodeposition of conductive polymers, metals, polyelectrolytes, etc.) in which the growth of the layer is in general determined by the quantity of charge (i.e. the time integral of the current).

Thus, considering a surface that is not an electrical equipotential, for example a wafer of a semiconductor material such as silicon for the fabrication of an integrated circuit, or else a surface covered with a semiconductor barrier layer of a metal nitride, such as titanium or tantalum nitride, any two points on this surface between which there exists a resistance of, for example, the order of ten kilohms will see an electrochemical potential differing by only a few hundred millivolts in the case of an electro-initiated reaction, whereas the potential difference may be up to several volts, or even several tens of volts in the case of an electro-mediated reaction. If the nature of the electrochemical reactions taking place on a biased surface is sensitive to potential differences of the order of 1 volt or a few volts, one might expect that on the contrary there would be much less of an effect caused by situations separated by only a few hundred millivolts. Thus, electro-initiated reactions are intrinsically less sensitive to the effects of a minor ohmic drop, like those that may occur in an imperfect electrochemical cell. In addition, electro-mediated reactions are intrinsically “potential threshold” reactions, that is to say there exists an electrical potential above which the characteristics of the film deposited (especially the degree of grafting and the thickness), for the same solution composition, are quite simply insensitive to ohmic drop effects. Let V_{block} be the potential (in absolute value) above which the maximum degree of grafting is obtained (saturation of the surface), for example following deposition at a fixed potential. A bias of V_{block}+δV, i.e. above the blocking potential, will, in the same solution, lead to the same film, since the maximum degree of grafting is also obtained at this potential. Since the thickness, for the maximum degree of grafting, depends only on the length of the chains and therefore solely on the chemical composition of the solution, a film having the same characteristics is obtained for any potential protocol involving at least one range above V_{block}. The potential V_{block} may easily be determined for a given polymer by plotting a graph of the amount of polymer grafted as a function of the applied potential, the potential V_{block} corresponding on this graph to the potential (in absolute value) above which the degree of polymer grafting remains a maximum.

To summarize, electro-initiated reactions possess an intrinsic property that electro-mediated reactions do not possess—they have the advantage of evening out the effects of ohmic drop over a surface not forming an electrical equipotential. A homogeneous coating of uniform thickness may thus be easily obtained on a non-equipotential surface by depositing it via an electro-initiated reaction. All that is required is to bias the surface using a protocol that includes a potential range (in absolute value) above V_{block}+δV, where δV is the largest potential drop over the surface to be treated, owing to the electrical contacting that has been effected. This characteristic of electro-initiated reactions makes it possible in particular to obtain conformal coatings even on surfaces having high aspect ratios, and therefore in regions having a very small radius of curvature (edges, tips, etc.). Electro-initiated reactions essentially prove to be sensitive to the geometric topology of the surface, but not to its ohmic drop distribution.

These reactions therefore constitute suitable reactions for obtaining conformal organic according to the invention, within which the metallic material can form from its precursor, as illustrated in the exemplary embodiments presented below.

Another category of reactions that can be used for producing thin uniform organic films on the surfaces of conductors and semiconductors in the process of the present invention comprises electro-polymerization reactions that result in electrically insulating polymers.

Electropolymerization reactions are polymerization reactions initiated by a charge transfer reaction, and the progress of which electropolymerization results from a succession of reactions, including, in particular, charge transfer reactions. These are therefore reactions that are intrinsically different from the electrografting reactions described above, as they are not electro-initiated but electro-mediated reactions—the electropolymer continues to form as long as the potential of the working electrode is sufficient to maintain all the charge transfer reactions. In general, these reactions lead to an organic coating on the surface, by precipitation of the polymer formed near the surface. The electropolymerization reactions do not in general lead to grafting, within the context of the previous section. One good way of distinguishing them consists, for example in depositing the polymers on a rotating electrode, rotating at high speed. In the case of the electropolymerization of pyrrole, polymer is no longer observed on the electrode, at the end of reaction, whenever its rotation speed is greater than 5000 rpm. In the case of the electrografting of methacrylonitrile, polymer is obtained on the surface of the electrode even at 10000 rpm, that is to say above the turbulence threshold. Furthermore, it is observed that the amount of grafted polymethacrylonitrile is the same as that when the electrode is not rotating, as described by P. Viel, C. Bureau, G. Deniau, G. Zalczer and G. Lécayon in “Electropolymerization of methacrylonitrile on a rotating disk at high spinning rate”, Journal of Electroanalytical Chemistry, 470, 14 (1999).

Likewise, it is possible to electrograft only molecules carrying vinyl groups or rings that can be cleaved by nucleophilic or electrophilic attack, and only certain specific precursors may be electropolymerized. According to the invention, in particular pyrrole, aniline, thiophene, acetylene and their derivatives can be used, these resulting in the formation of conductive polymers. Since the polymers formed from these precursors are conductive, their formation and their precipitation on the surface do not block the working electrode, and these polymers may continue to “grow” on themselves as long as the electrical current is maintained. The amount of polymer formed depends on the quantity of electric charge (i.e. the time integral of the current) that has passed through the circuit. Therefore more polymer forms in the regions of high electric field, where the local currents are more intense. This characteristic of the electropolymerization of conductive polymer precursors stems from reactions that are less useful for obtaining uniform, and especially conformal, films on surfaces having a non-uniform ohmic drop topology, and especially when the surface of the working electrode is highly structured, as is in particular the case in microelectronics. Their use for the present invention will be more appropriate to the situations in which the thickness differences between two regions of the working electrode remain less than the permitted tolerance on the uniformity and conformality of the coating.

However, certain organic film precursors that can be electropolymerized do exist, but the electropolymer produced from them is insulating. This is the case for example with diamines, and especially ethylenediamine, 1,3-diaminopropane and other diamines. For example, the electropolymerization of ethylenediamine results in the formation of polyethyleneimine (PEI), which is a hydrophilic insulating polymer. Unlike the precursors of conductive polymers, diamines result in an insulating polymer, which precipitates on the surface and passivates it—the growth of the electropolymer is therefore self-limited, in this case by its precipitation, which is a non-electrochemical phenomenon. Consequently, just as in the case of electrografting reactions, the formation of the layer becomes independent of the electrical current and is dictated only by the precipitation, which means that it is also independent of the electric potential topology and therefore makes it possible to obtain uniform, and in particular conformal, coatings that can be used for implementing the process of the present invention.

In the description that follows, the present invention will be illustrated in a non-limiting manner in the case of the formation of a copper seed layer on a TiN, TiN(Si) or TaN barrier layer for copper interconnects in microelectronics. It will be clearly apparent to those skilled in the art that this restriction does not detract from the generalization of the invention, nor from the case of metal seeds layers on any surface with, if necessary, an electrically conductive or semiconductive barrier layer, nor from the formation of uniform, and especially conformal, metal layers having functions other than that of a barrier layer, and in fields of application other than the present invention.

### BRIEF DESCRIPTION OF THE DRAWINGS

In these figures, “g” stands for grafted (i.e. an organic film grafted onto a surface); “eg” stands for electrografted; “h” stands for the thickness of the organic film; “Tr (%)” stands for the transmission in %; “ν (cm⁻¹)” stands for the wavenumber in cm⁻¹; “F (Hz)” stands for the frequency in hertz; “Imp (Ω)” stands for the impedance in ohms; “E(eV)” stands for the energy in eV; “ref” stands for reference; “prot” stands for protocol; and “dd” stands for diazo-dipped.

FIG. 1 shows one method of implementing the process of the present invention, which comprises: step (a) of depositing an organic film “OF” on a surface “S” etched with a recess “R” (the width of the etched feature being indicated by “L”), the etched surface having a barrier layer “BL”; step (b) of inserting a precursor “pM” of a metallic material into the organic film OF; step (c) of converting the precursor pM into the said metallic material within the said organic film in order to form the seed film (SF) according to the invention; and step (d) of filling the recess with the said metallic material in order to obtain a metal layer (ML).

FIGS. 2a and 2b show a schematic enlargement of the steps (b) and (c) shown in FIG. 1 when the organic film (OF) is grafted onto the surface S. In FIG. 2a, the organic film has already been grafted onto the surface (the black dots indicate the points where the film has been grafted onto the surface) and the precursor (pM) of the metallic material has been inserted into this organic film. The depth of penetration of the precursors into the film has been arbitrarily shown here as complete penetration, that is to say the precursors are buried within the film up to the point of “touching” the surface. In fact, filling may be only partial (for example if the filling solvent is only a poor swelling agent for the electrografted film). In FIG. 2b, the precursor of the metallic material has been converted into the said metallic material within the said organic film to form the seed film SF of the present invention on the surface S. Likewise, the effective proportion of the volume of the electrografted film finally occupied by the metal layer will depend on the quantity of precursor ions that were attached to and/or inserted into the said film.

FIGS. 3a and 3b show a schematic enlargement of the steps (b) and (c) shown in FIG. 1 when the organic film (OF) has been deposited on the surface S. In FIG. 3a, the organic film has already been deposited on the surface and the precursor (pM) of the metallic material has been inserted into this organic film. In FIG. 3b, the precursor of the metallic material has been converted into the said metallic material within the said organic film to form the seed film SF of the present invention on the surface S. The effective depth of penetration of the precursors into the film has been arbitrarily set in this case to the thickness of the film deposited, but intermediate situations in which the penetration is only partial (or even when there is only attachment on the surface of the film) are also acceptable as regards the present invention since they also make use of the conformality of the organic film.

FIG. 4 shows the molecular details of one method of implementing the present invention according to the process shown in FIG. 2 (grafted organic film). The thickness (h) of the grafted organic film (OF) is 100 nm, the surface is a 316L stainless steel surface and “g” indicates the points where the molecules constituting the organic film have been grafted. The precursor (pM) of the metallic material is in this case in the form of copper ions, in order to obtain a copper seed film. Since the organic film is a P4VP film, it may be entirely filled with cupric ions in aqueous medium, and incompletely filled in an organic (acetonitrile, etc.) medium or a highly acid aqueous medium.

FIGS. 5a, 5b and 5c show IRRAS (infrared reflexion absorption spectroscopy) spectra of P4VP films of 100 nm thickness on nickel before (5a) and after (5b) being dipped for 10 minutes in a 5 g/l aqueous copper sulphate solution. The splitting of the peak at 1617 cm⁻¹ is characteristic of the formation of copper/pyridine complexes, proving that the solution has penetrated into the film. FIG. 5c shows a spectrum after the film has been treated in acid medium.

FIGS. 6a, 6b and 6c show IRRAS spectra for a strip obtained, respectively, according to the same protocol as that of FIG. 5a (FIG. 6a), charged with cupric ions according to the same protocol as that of FIG. 5b (FIG. 6b) and then for a strip according to FIG. 6b treated for 5 minutes in a 9 mol/l ammonium hydroxide solution (FIG. 6c).

FIG. 7 is a photograph of three strips obtained by fixing copper onto a 316L stainless steel surface using an organic film consisting of P4VP electrografted according to the process of the present invention. The copper deposited from its precursor in the film was obtained by potentiostatic electroplating of variable duration. This figure shows, from left to right, the result of electroplating for 50 seconds (strip (a)), 120 seconds (strip (b)) and 240 seconds (strip (c)), respectively.

FIG. 8 shows XPS (X-ray photoelectron spectroscopy) spectra for the strips of FIG. 6, in the 2p copper orbital region. Spectrum (a) is that obtained after the stainless steel strips covered with the electrografted P4VP film have been dipped into the cupric ion solution (see Example 1); spectra (b), (c) and (d) are those obtained after electrodeposition, from the copper precursor, of copper in the P4VP films, showing the progressive conversion of the cupric ions of the film into copper atoms.

FIGS. 9a and 9b are infrared spectra for strips obtained in particular during various steps of the process of the invention. To obtain these spectra, a P4VP film was deposited on a gold strip (surface) by spin coating. Spectra (a) and (d) correspond to the virgin P4VP film; spectra (b) and (e) correspond to the P4VP film in which a copper precursor had been inserted by dipping the strip into a concentrated copper solution (+CuSO₄); spectrum (c) corresponds to the P4VP film into which the copper precursor was inserted as previously and then converted into copper, and the seed film thus obtained (m+r) rinsed; and spectrum (f) corresponds to the P4VP film into which the copper precursor was inserted as previously and then rinsed (r), the conversion of the precursor not having been carried out.

FIG. 10 shows a graph of the impedance (Imp) measurements (in ohms, in the frequency range between 0.5 Hz and 100 kHz obtained between two points on a silicon strip measuring 2×10 cm, covered by CVD (chemical vapour deposition) with a TiN layer about 20 nm in thickness. A first electrical contact was made using a crocodile clip at one end of the strip and a second contact was made in the same manner at increasing distances from the first, from 5 to 45 mm, to within a precision of the order of 1 mm.

FIGS. 11 and 12 show XPS surface analysis spectra obtained on a strip obtained by grafting an organic film onto TiN by the electroreduction of diazonium salts. The dotted lines relate to TiN alone and the continuous line to diazo-grafted TiN (diazo-g-TiN).

FIG. 13 shows the N1s region of the XPS surface analysis spectra of a TiN strip dipped into a 4-nitrophenyldiazonium tetrafluoroborate solution in acetonitrile for 24 hours (dd(10⁻³M/24 h)-TiN) as comparison with the initial TiN strip and of a diazo-electrografted TiN strip (diazo-eg-TiN).

FIG. 14 shows the N1s region of the XPS surface analysis spectrum of a silicon strip covered, by CVD, with a 20 nm layer of TiN(Si), immersed in a 4-vinylpyridine solution in dimethylformamide, in the presence of tetraethylammonium perchlorate (P4VP-g-TiN(Si)) for comparison with that of the starting TiN(Si) strip.

FIG. 15 shows XPS surface analysis spectra obtained on a TiN strip covered with P4VP and connected to a potentiostat as working electrode, demonstrating the insertion of a copper precursor (copper sulphate [CuSO₄.5H₂O]) into the P4VP film. The copper 2p orbital region of the XPS spectrum of the strip is shown in the upper part of FIG. 15.

FIG. 16 shows the N is region of the XPS spectrum of FIG. 15. In FIGS. 15 and 16, “ni” stands for measurements at normal incidence and “gi” at grazing incidence.

FIGS. 17, 18 and 19 compare the profiles, obtained by means of an atomic force microscope (AFM), of substrates having etched features in the form of regularly spaced trenches, before and after coating with a seed film of a metallic material obtained by the processes of the present invention. Z represents depths in nm, x represents widths in μm and “g”=grafted.

FIGS. 20 and 21 are SEM (scanning electron microscopy) micrographs of a silicon substrate having regular etched features in the form of trenches about 200 nm in width and spaced apart by 300 nm, these being coated with a titanium nitride barrier layer of about 10 nm and coated with an electrografted polymer film (P4VP) used for producing a seed layer according to the present invention, showing the conformality of the coating. In FIG. 20 the magnification is ×100000 (the scale is indicated by the dots and the 300 nm dimension on the micrograph) and in FIG. 21 the magnification is ×150000 (the scale is indicated by the dots and the 200 nm dimension on the micrograph).

FIGS. 22 and 23 are SEM micrographs of a silicon substrate having regular etched features in the form of trenches about 200 nm in width, spaced apart by 300 nm, and having a depth of 400 nm, these being coated with a titanium nitride barrier layer of about 10 nm and coated with a film of an electrografted diazonium salt serving for the production of a seed layer according to the present invention, showing the conformality of the coating. In FIG. 22, the is magnification is ×60000 and in FIG. 23 it is ×110000 (in the micrographs, the scales are indicated by the dotted lines and the 500 and 173 nm dimensions, respectively).

FIG. 24 is an SEM micrograph showing the effect produced by the same treatment as that used to obtain the results shown in FIGS. 22 and 23, but with a finer etching resolution, namely 0.12 μm. The magnification is ×50000 (the scale is indicated by the dots and the 600 nm dimension in the micrograph).

FIG. 25 is an SEM micrograph of a trench in a silicon substrate with no etched features (planar surface) coated with a titanium nitride barrier layer of about 10 nm and with an electrografted P4VP film serving for producing a seed layer according to the present invention, showing the conformality of the coating. The magnification is ×35000 (in the micrograph, the scale is indicated by the dots and the 857 nm dimension). The dashed lines indicate the different layers of materials.

FIG. 26 is an SEM micrograph of a trench in a silicon substrate with etched features, the trench being coated with a titanium nitride barrier layer of about 10 nm, with a seed film based on an electro-grafted diazonium salt and with a copper layer formed from, and on, the seed layer, showing the conformality of the copper coating on the etched features. The magnification is ×25000 (in the micrograph, the scale is indicated by the dots and the 1.20 μm dimension).

FIG. 27 is an SEM micrograph obtained at another point on the substrate of FIG. 26. The magnification is ×35000 (the scale is indicated on the micrograph by the dots and the 857 nm dimension).

FIG. 28 is an SEM micrograph of trenches in a coupon showing the formation, on TiN, of a copper seed layer, estimated to be about 10 nm in thickness, obtained from an electrografted aryldiazonium film.

FIG. 29 is an SEM micrograph of trenches in a coupon showing the filling, with copper, of 0.22 μm trenches having a seed layer obtained beforehand by electrografting a palladium-metallized aryldiazonium.

FIG. 30 is a macroscopic photograph of a planar silicon wafer with a 400 nm SiO₂ layer and a 10 nm TiN layer, bearing a copper layer obtained by electrografting from a 4-VP solution and copper precursors in DMF. The TiN surface was scratched down to the silica, and it was observed that the coating was deposited only on the part that had been dipped into the electrografting bath and that was connected via the TiN.

FIG. 31 is a photograph of a structured coupon after a seed layer obtained by electrografting 4-VP and ECD: (1) region with seed layer; (2) region with seed layer+ECD; (3) region with only a barrier.

FIG. 32 is an SEM micrograph of trenches in a coupon showing the filling, with copper, of 0.22 μm trenches bearing a seed layer obtained beforehand by electrografting from a solution of 4-VP and copper precursors.

### EXAMPLES

### Example 1

### Filling of an Ultrathin Film of poly-4-vinylpyridine (P4VP) Electrografted onto Gold with Ionic Precursors

This example demonstrates that the present invention makes it possible to retain, and make use of, the complexation properties of a poly-4-vinylpyridine (P4VP) film, even when this is very thin—in this case it may have a thickness of around 30 nm.

This example illustrates, generically, the fact that an ultrathin organic film can be filled with metal precursors in ionic form. It also illustrates the fact that the complexing properties of the film are a good means of overcoming the spontaneous re-expulsion of the precursors out of the film when this film, once it has been filled and despite the unfavourable diffusion gradients, is dipped into a solution containing no precursors.

Starting with a gold strip—5 μm of gold evaporated by Joule heating onto a glass microscope slide, pretreated with a film of chromium serving as adhesion primer—an electrografted P4VP film 30 nm in thickness was produced by subjecting the gold surface, dipped into a 40 vol % solution of 4-vinylpyridine in DMF (dimethylformamide) in the presence of 5×10⁻² mol/l of TEAP (tetraethylammonium perchlorate), to 50 voltammetric scans from −0.7 to −2.7 V/(Ag⁺/Ag) at 200 mV/s. To do this, a platinum counterelectrode of large area was used. This electrografted film constituted the organic film within the context of the present invention.

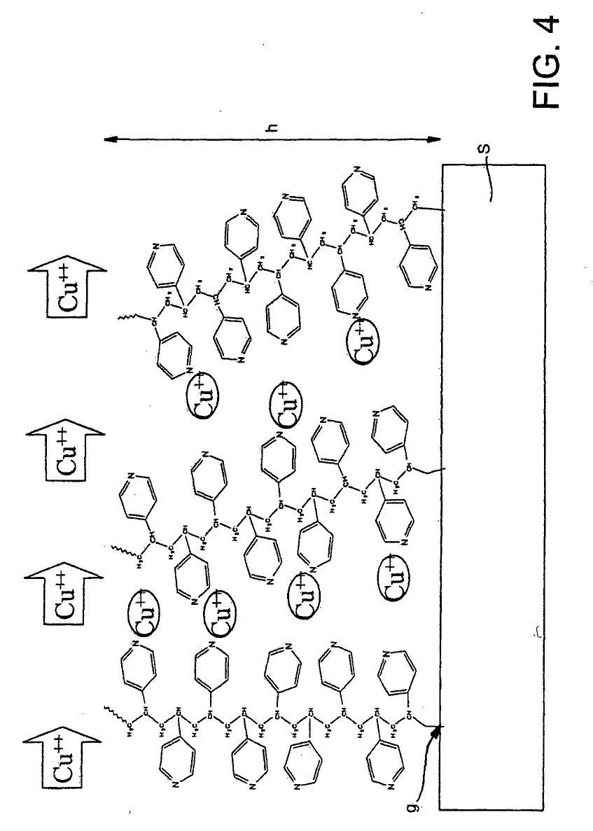

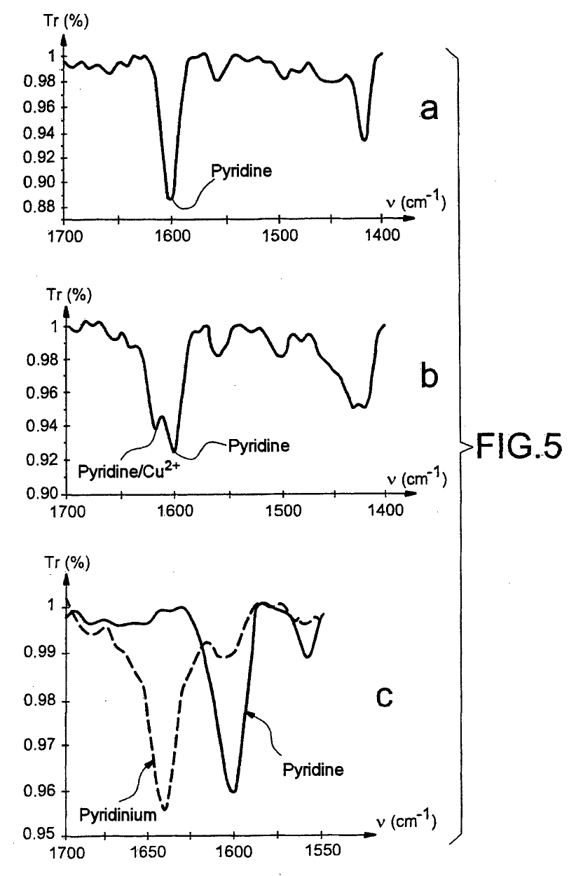

The strip thus treated was rinsed with DMF and then dried in a stream of argon. Its IRRAS spectrum was obtained. Enlargement of the region located between 1400 and 1700 cm⁻¹ showed the presence of peaks characteristic of the vibrations of the pyridine ring of the polymer formed, and in particular the peak at around 1605 cm⁻¹ (FIG. 5a). The strip was then dipped for 25 minutes in a stirred solution of 10 g of copper sulphate [CuSO₄.5H₂O] as precursor of the metallic material (in this case copper) according to the invention in 200 ml of deionized water in order to insert this precursor into the organic film. One of the structures obtained according to this example is shown schematically in FIG. 4 where “g” indicates the points at which the film is grafted onto the surface, Cu²⁺ indicates the precursor of the metallic material and h (=100 nm) indicates the thickness of the organic film.

The strip was then rapidly rinsed with a few jets of deionized water and then dried in a stream of argon. Its IRRAS spectrum is shown in FIG. 5b, in which it may be seen that the peak characteristic of the pyridine ring is split, with the appearance of an additional peak at around 1620 cm⁻¹. This new peak is due to quaternized pyridine rings, this quaternization being accompanied by the formation of pyridine/Cu²⁺ complexes, since the same splitting is observed when P4VP is simply quaternized by treatment in acid medium (FIG. 5c). It therefore characterizes the complexation of copper by the ultrathin film.

The IRRAS spectrum of FIG. 5b is not modified when the strip is re-immersed, this time into a stirred solution of deionized water at room temperature for 25 minutes, removed and then dried with a stream of argon. This shows that the complexing properties of the electrografted film prevent the precursors from coming out of the film when it is re-immersed into a solution containing no precursors.

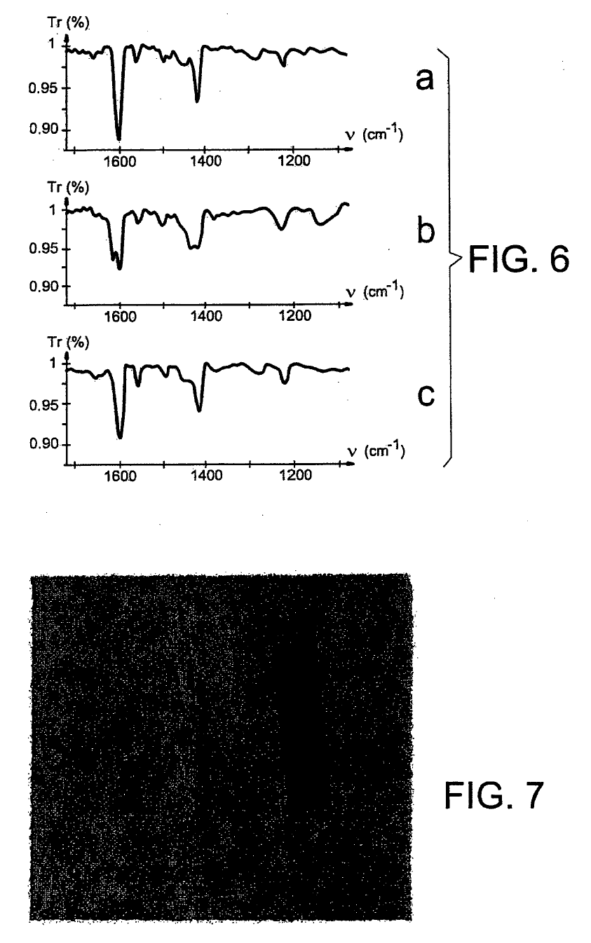

The inventors have noted that there is decomplexation and expulsion of the cupric ions out of the film when the latter is dipped either into a hot (80C) deionized water solution or into an ammonium hydroxide solution. FIG. 6 show the IRRAS spectra of a strip obtained according to the above protocol (FIG. 6a), charged with cupric ions according to the above protocol (FIG. 6b), and then treated for 5 minutes in a 9 mol/l ammonium hydroxide solution (FIG. 6c). Similar spectra were obtained by treating the film charged with cupric ions in boiling water for 25 minutes.

### Example 2

### Electroreduction of Metal Precursors within an Ultrathin Film of poly-4-vinylpyridine (P4VP) Electrografted onto 316L Stainless Steel

This example illustrates the reduction of precursor ions trapped beforehand in a polymer film electrografted onto a metal surface. A metal film, identifiable by photoelectron spectroscopy, was thus able to be formed within the electrografted film. The reduction was carried out by electrolysis in a solution containing precursor ions. This also illustrates the fact that it is possible to obtain a metal film within an organic film according to one method of implementation in which the trapping of the precursors and the formation of the metal film take place in a single bath.

A thin P4VP film was formed using the same protocol as that of the above Example 1 on three 316L stainless steel strips (strips (a), (b) and (c)) measuring 1×10 cm, degreased beforehand by ultrasonic treatment in dichloromethane. The strips were rinsed with DMF, dried in a stream of argon and then dipped for 25 minutes into a solution of 10 g of copper sulphate [CuSO₄.5H₂O] in 200 ml of deionized water. With a platinum counterelectrode also immersed in the solution, each of these strips was subjected, one after another, to a cathodic bias at constant potential of −1.15 V/SCE for a time t=50 seconds (strip (a)), 120 seconds (strip (b)) and 240 seconds (strip c)).

The strips were then ultrasonically rinsed with DMF for 2 minutes and dried in a stream of argon. They are shown in the photograph of FIG. 7.

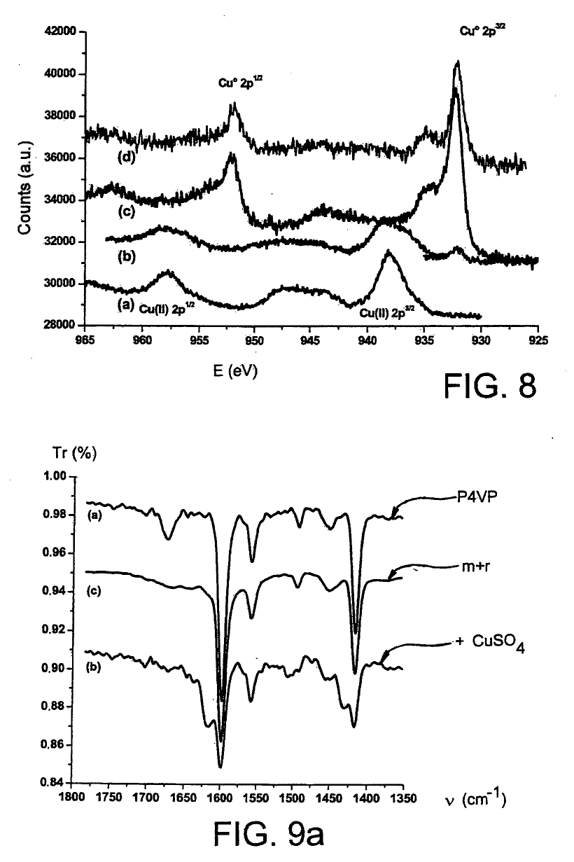

The strips were analysed using photoelectron spectroscopy. The results of this analysis are shown in FIG. 8. In this figure, the spectrum of strip (a) is that obtained, in the copper 2p orbital range, just after the step of dipping it into the cupric ion solution, that is to say before reduction of the precursors in the P4VP film. The 2p^{1/2} and 2p^{3/2} lines of the cupric ions are observed in this figure, at around 938 and 958 eV respectively. Spectrum (b) is that obtained after biasing for 50 s, which shows, after rinsing, essentially the cupric ions and a very slight shoulder at around 932 eV characteristic of the 2p^{3/2} levels of metallic copper. Spectra (c) and (d) are those obtained after deposition of the reinforcing material after being biased for 120 and 240 s, respectively. They clearly show the disappearance of the 2p level peaks of cupric ions, in favour of those of the 2p levels of metallic copper, demonstrating the formation of a metal coating.

The pictures in FIG. 7 clearly show that a copper coating has formed on the surface in the case of the strips that have undergone sufficient bias. This coating is adherent and, in particular, it resists being ultrasonically washed for 2 minutes in DMF.

### Example 3

### Direct Attachment of a Seed Film from an Organic Film of a Polymer Deposited by Spin Coating

This example illustrates the formation of a metal film from precursors of the metallic material that are trapped in a polymer film simply deposited on a metal surface by spin coating. The polymer was resistant to the dipping bath, which allowed the precursors to be trapped owing to the fact that it was merely swollen by this bath, but not being soluble therein.

In this example, the organic film was deposited by spin coating using a solution containing 5 wt % of P4VP in DMF, so as to obtain a P4VP coating of about 100 nm on a gold strip similar to that of Example 1. The strip thus treated was dried with a hair dryer and then dipped for 25 minutes into a solution containing 10 g of copper sulphate in 200 ml of deionized water in order to insert the precursor of the metallic material. The strip was then rinsed with deionized water and then immersed in an electrolysis bath containing 2 g of copper sulphate and 3 g of NaCl in 500 ml of deionized water in order to convert the precursor of the metallic material into the said metallic material, in this case copper. It was then subjected to 10 voltammetric scans between 0 and −0.5 V/SCE at 200 mV/s, removed from the bath, rinsed with deionized water and then decomplexed of the excess cupric ions by dipping it for 20 minutes into a 10% aqueous ammonia solution and finally rinsed by immersion for 2 h 30 min in a DMF solution.

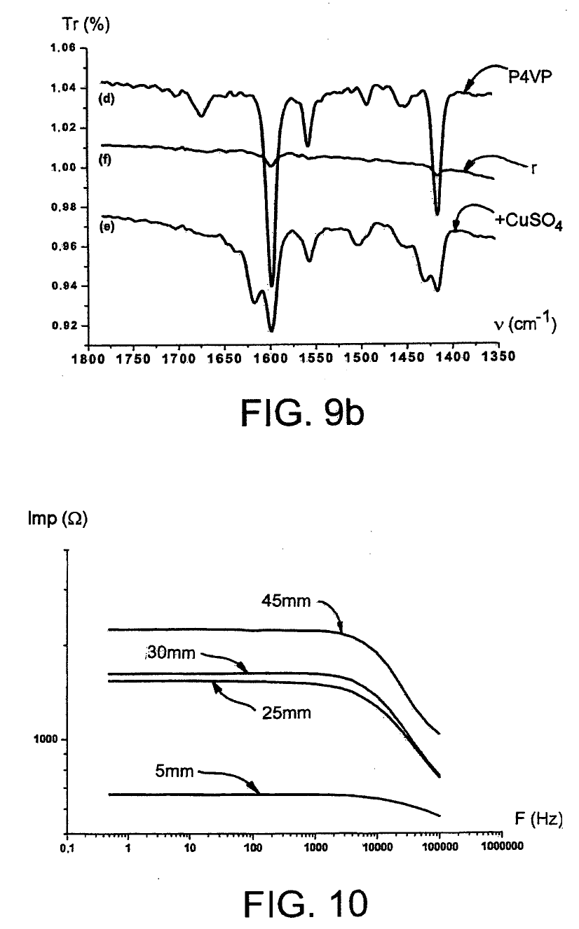

FIGS. 9a and 9b show the infrared spectra of the strips obtained at the various steps above, in the region of the vibration modes of the pyridine ring of the polymer. Spectra (a) and (d) (FIGS. 9a and 9b) are identical and correspond to the P4VP film deposited on the gold surface by spin coating. The band at 1600 cm⁻¹ is characteristic of the pyridine group. Spectra (b) and (d) (FIGS. 9a and 9b) were obtained after dipping the strip covered with the P4VP film into the concentrated copper solution. A splitting of the previous peak is observed, with the appearance of a second peak at around 1620 cm⁻¹, characteristic of the complex formed between the pyridine rings and the cupric ions. Spectrum (c) (FIG. 9a) is that obtained after reduction of the cupric ions according to the above protocol. This clearly shows the bands characteristic of the P4VP film as deposited originally, except that this film has withstood being rinsed in DMF for 2 h 30 min. Visual examination of the strip showed that there was a copper coating. Spectrum (f) (FIG. 9b) is that obtained by carrying out the steps of rinsing the strip directly after it had been dipped into the solution containing the precursors, without carrying out the reduction. This shows that the film was almost completely washed away.

Since the P4VP was therefore washed away by a DMF solution with ultrasound, these results show that the reduction of the metal precursors into the said metallic material does indeed take place within the film, since this reduction helps to make the film insoluble and prevent it from being washed away by a subsequent treatment in a rinsing solution, even when this solution is a good solvent for the initial organic film.

### Example 4

### Ohmic Drop Along a Titanium Nitride (TiN) Surface

This example illustrates the case in which a surface does not constitute an equipotential surface, and therefore exhibits a topological distribution of ohmic drop. The examples that follow will illustrate that it is possible to produce uniform, or even conformal, metal films on such surfaces, whereas this is impossible with the techniques of the prior art. The illustration relates to a strip of titanium nitride (TiN), which is semiconductive.

An electrical contact was made using a crocodile clip at one end of a 2×10 cm silicon strip coated, by CVD, with a TiN layer of about 20 nm thickness. A second contact was made in the same manner at increasing distances, from 5 to 45 mm, from the first.

The impedance between these two points was measured within the frequency range from 0.5 Hz and 100 kHz (FIG. 10), with the following results: 666Ω at 5 mm; 1540Ω at 25 mm; 1620Ω at 30 mm; and 2240Ω at 45 mm. This shows that the impedance of the circuit was almost constant over the entire frequency range, the impedance level being higher the further apart the two contact points on the titanium nitride. By plotting the impedance, measured on the plateaux of FIG. 10, as a function of the distance between the two points, the resistance is determined to be around 400 ohms/cm.

This places the maximum ohmic drop between the edge and the centre of a 300 mm thick printed-circuit wafer at 600 mV for a current of 100 μA, which, as will be seen later, remains acceptable for obtaining conformal coatings obtained for example by electro-grafting according to the process of the present invention.

### Example 5

### Grafting of an Organic Film onto TiN via the Electroreduction of Diazonium Salts

This example illustrates the formation of an organic film on titanium nitride by the electrografting of diazonium salts, titanium nitride being a material used in the production of barrier layers in damascene and dual damascene processes in microelectronics. This method of synthesis is convenient as the diazonium salts may be variously prefunctionalized especially by complexing functional groups, so as to produce layers of metal film precursors. In addition, the organic film obtained is very thin (thickness of less than 10 nm), which makes this method of implementation very useful for producing seed layers according to the invention in microelectronic applications for very fine (100 nm or less) resolutions. Admittedly the organic film obtained in this case does not include complexing groups capable of complexing metal precursors similar to the P4VP films of the previous examples, but it is known that this can be easily achieved by prefunctionalizing the starting diazonium salt with suitable groups (for information, it is known for example to reduce nitro groups of electrografted 4NPD films into amine (NH₂) groups by chemical treatment: these amine groups are very good complexing agents for various metal precursors, and especially cupric ions). However, this example does show that the electrografting of diazonium salts constitutes a good candidate for producing highly adherent organic films having functional groups made to order.

A TiN strip identical to that of the above Example 4, a platinum counterelectrode and an Ag⁺/Ag reference electrode were immersed in a 5×10⁻³ mol/l solution of 4-nitrophenyldiazonium (4NPD) tetrafluoro-borate in 5×10⁻² mol/l acetonitrile in TEAP. Three voltammetric scans from +1.15 to −1.52 V/(Ag⁺/Ag) were performed on the TiN strip. The strip was then ultra-sonically rinsed for 2 minutes in acetonitrile and then dried in a stream of argon.

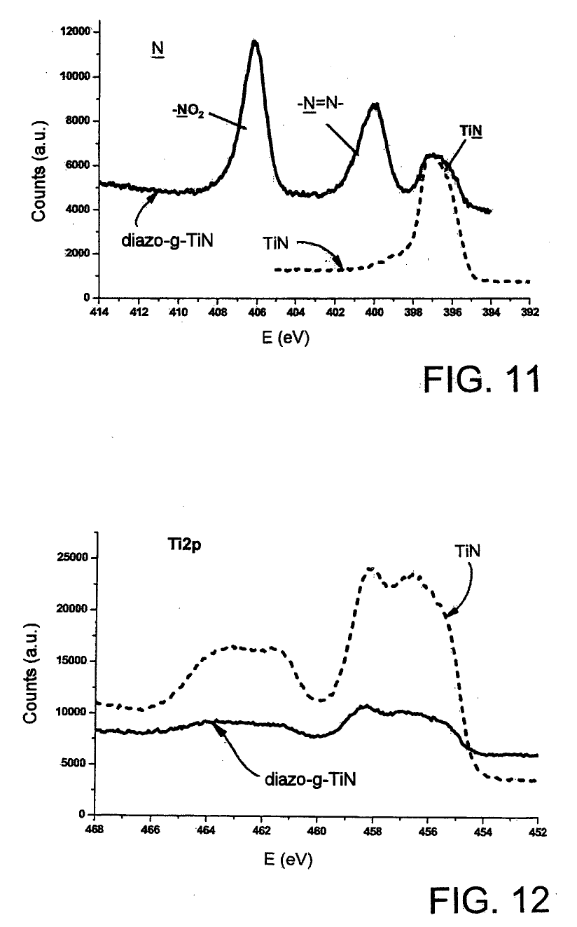

The N1s region of the XPS spectrum of the strip thus treated is shown in FIG. 11, for comparison with that, in the same energy range, of the TiN strip before treatment. This shows the peak of the nitrogen atoms of TiN at 397 eV and, on the treated strip, the characteristic peaks at 406.5 eV of the nitro (NO₂) groups from the 4-nitrophenyl radicals grafted onto the surface. At the same time, the intensity of the peak at 397 eV on the treated strip is seen to be lower, which shows the formation of a film on this surface with, however, a thickness of less than about 10 nm (which is the depth of penetration of the XPS) and suggests the formation of a very thin film. This was confirmed by comparing the XPS spectra of the strips before and after electrografting in the titanium 2p orbital region (FIG. 12), which shows a very strong reduction in the titanium peaks after treatment, although these are still present.

The peak at around 400 eV is known in the literature on the electrografting of diazonium salts and corresponds to the formation of diazo (—N═N—) groups resulting from parasitic copulation between radicals produced by the electroreduction of the diazonium salts and groups already grafted.

### Example 6

### Grafting of an Organic Film onto TiN by Dipping into a Solution Containing Diazonium Salts

This example illustrates the possibility of using diazonium salts to carry out direct chemical grafting of an organic layer onto barrier layers by simple dip coating. Since diazonium salts are readily prefunctionalizable, this example shows how it is possible to apply the present invention via a succession of currentless steps, that is to say using an electroless process.

A TiN strip identical to that of the above Example 5 was dipped into a 10⁻³ mol/l solution of 4-nitrophenyldiazonium (4NPD) tetrafluoroborate in acetonitrile for 24 hours. The strip was then removed, rinsed by rapidly dipping it into acetonitrile followed by immersion for 2 minutes in deionized water with ultrasound, and then dried in a stream of argon.

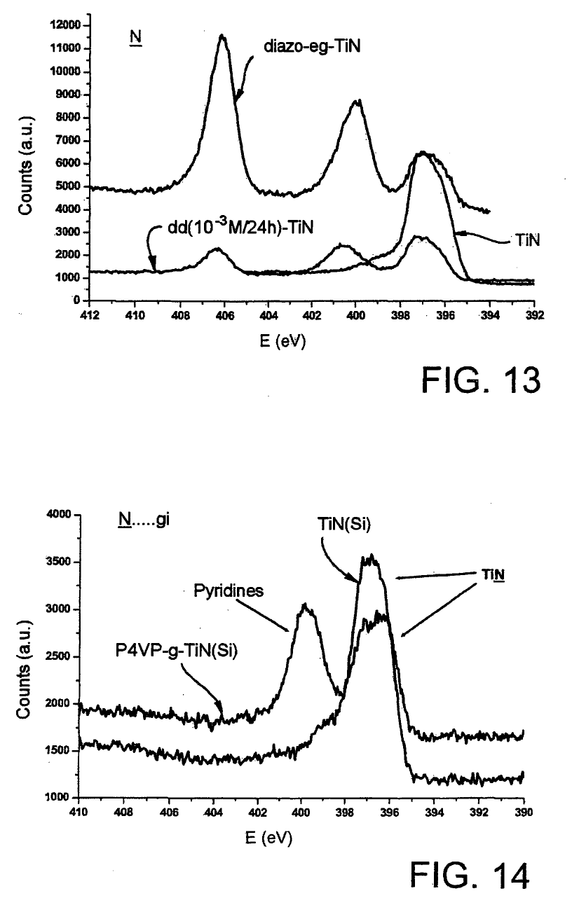

FIG. 13 shows the N1s region of the XPS spectrum of the surface thus treated, for comparison with, on the one hand, the initial TiN strip and, on the other hand, with the organic film obtained according to Example 5. This shows, at around 400.5 eV and 406.5 eV respectively, the peaks characteristic of a layer of 4-nitrophenyl radicals grafted onto the surface. It was observed that the organic film thus obtained was much thicker than that of Example 5.

This result therefore indicates that the electroless plating from diazonium salts may constitute a useful way of achieving ultrathin thicknesses, this being easier to use the more spontaneous the attachment of the radicals associated with the initial diazonium salt.

### Example 7

### Electrografting of a P4VP Film onto TiN(Si)

This example shows how to extend the method of implementation shown in the previous Example 1 to the case of the surface of a barrier layer such as that used in damascene or dual damascene processes in micro-electronics. The barrier layer used here is called TiN(Si) and corresponds to titanium nitride lightly doped with silicon.

A silicon strip, coated by CVD with a 20 nm layer of TiN(Si), immersed in a 40 vol % solution of 4-vinylpyridine in dimethylformamide (DMF), in the presence of 5×10⁻² mol/l of tetraethylammonium per-chlorate (TEAP), was connected to a potentiostat as working electrode. The circuit was completed with a platinum counterelectrode and a reference electrode based on the (Ag⁺/Ag)-(AgClO₄/TEAP) pair. The TiN(Si) electrode was subjected to 25 voltammetric scans from −0.6 to −2.9 V/(Ag⁺/Ag) at 200 mV/s. The strip was rinsed with DMF and then dried in a stream of argon.

FIG. 14 shows the N1s region of the XPS spectrum of the strip thus treated, for comparison with that of the initial TiN(Si) strip. It clearly shows the appearance of a peak at around 400 eV, characteristic of nitrogen atoms of the pyridine groups of the P4VP, and also a reduction of the peak due to the nitrogen atoms of the TiN(Si) on the surface of the substrate. The presence of the latter peak shows that the P4VP film obtained had a thickness of less than 10 nm.

### Example 8

### Formation of a Seed Film of a Metallic Material within a P4VP Film Electrografted onto TiN (Protocol 1)

This example illustrates the formation of a uniform metal film according to the invention on a semiconductor surface, despite the non-equipotential character of the surface. The protocol used in this case (called Protocol 1) was similar to that used on metal in the above Example 2. A single bath was used for filling the film with the metal precursors and for reducing these precursors within the film.

A P4VP film of about 30 nm thickness was deposited, using a protocol similar to that of Example 7, on a TiN strip of the above Example 4 by electrografting.

The TiN strip thus coated with P4VP, connected to a potentiostat as working electrode, was firstly immersed without any current for 25 minutes in an aqueous solution containing 11 g of copper sulphate [CuSO₄.5H₂O], 3 g of sulphuric acid H₂SO₄ (d=1.38) and 6 mg of sodium chloride NaCl, all these in 50 ml of 18 MΩ deionized water. A platinum counterelectrode and a saturated calomel reference electrode were added to the set-up. At the end of the dipping phase, the strip, which was not removed from the solution, was biased for 2 minutes at a potential of −0.5 V/SCE. The strip was then removed, rinsed with deionized water and then dried in a stream of argon.

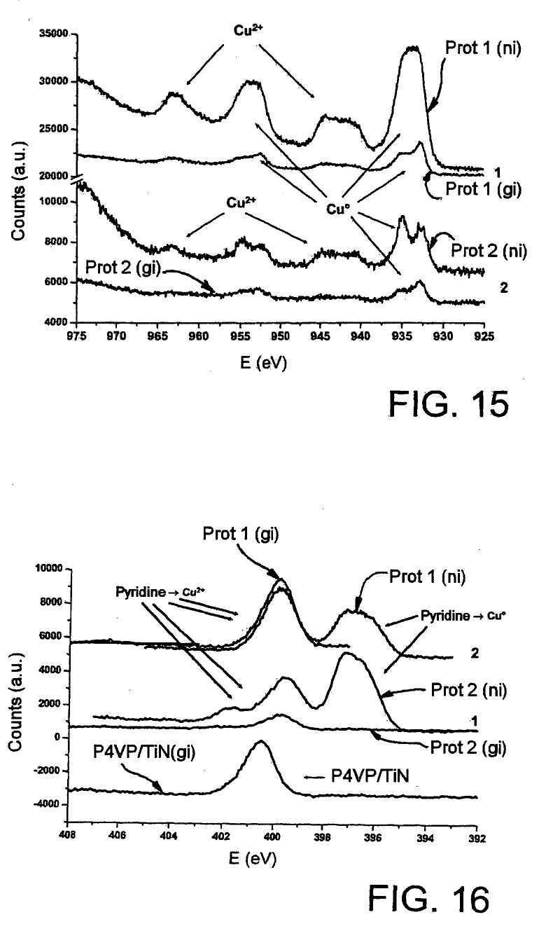

The copper 2p orbital region of the XPS spectrum of the strip is shown in the upper part of FIG. 15, and compares spectra obtained at normal and grazing incidence. Normal incidence makes it possible to obtain information over the entire depth of the XPS probe (i.e. about 10 nm), whereas grazing incidence is restricted to a very thin “skin”, and therefore provides information about the outermost surface of the specimen.

The peaks characteristic of cupric ions are observed at around 943 and 964 eV respectively, whereas those due to metallic copper are observed at around 933 and 954 eV respectively.

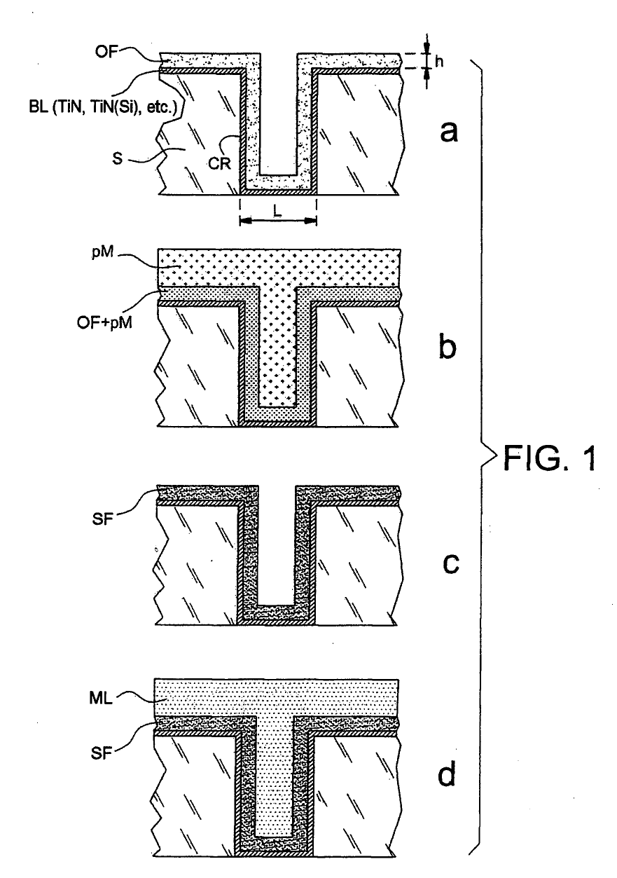

FIG. 15-1 (normal incidence) thus shows the formation of metallic copper within the P4VP film according to the invention. Visual inspection revealed a metal film of great uniformity, despite the fact that the TiN surface was not an equipotential surface, being a semiconductor. FIG. 16-1 shows the N1s region of the XPS spectrum. It may be seen that, at normal incidence, there are three peaks, at 397, 399.5 and 402 eV, which correspond respectively to the nitrogen atoms of the pyridine rings linked to the metallic (reduced) copper, to the nitrogens of the free pyridine rings, and to the nitrogens of the pyridine rings linked to the cupric ions. The disappearance of the peak at 397 eV in the spectrum obtained at the grazing incidence in FIG. 16-1 shows that the metallic copper is present at the bottom of the film, but not on the surface.

### Example 9

### Formation of a Metal Seed Film within a P4VP Film Electrografted onto TiN (Protocol 2)

This example uses a TiN strip coated with P4VP according to the same protocol as that of Example 8. It illustrates a second filling/reduction protocol (called Protocol 2) in which two successive baths are used, namely a bath for filling the film with the metallic precursors and then another bath for reducing the precursors within the film, the particular feature of the second bath being that it does not contain the said precursors. It is observed that the metal film obtained contains fewer precursors than in the previous case.

The TiN strip, coated with P4VP as in Example 8, was immersed for 25 minutes in an aqueous solution containing 11 g of copper sulphate [CuSO₄.5H₂O], 3 g of sulphuric acid H₂SO₄ (d=1.38) and 6 mg of sodium chloride NaCl, all these in 50 ml of 18 MΩ deionized water.

The strip was then removed from the solution, briefly rinsed in deionized water, connected to a potentiostat as working electrode and then immersed in a solution containing 3 g of sulphuric acid H₂SO₄ (d=1.38) and 6 mg of sodium chloride NaCl, both these in 50 ml of 18 MΩ deionized water. A platinum counterelectrode and a saturated calomel reference electrode were added to the set-up. The strip was biased for 2 minutes at a potential of −0.5 V/SCE, removed from the solution, rinsed with deionized water and then dried in a stream of argon.

The copper 2p orbital region of the XPS spectrum of the strip is shown in the lower part of FIG. 15, and this compares the spectra obtained at normal and grazing incidence. Normal incidence provides information about the entire probe depth of the XPS (i.e. about 10 nm), whereas grazing incidence is restricted to a very thin “skin”, and therefore provides information about the outermost surface of the specimen.

The peaks characteristic of cupric ions are observed at around 943 and 964 eV respectively, whereas those due to metallic copper are obtained at around 933 and 954 eV respectively.

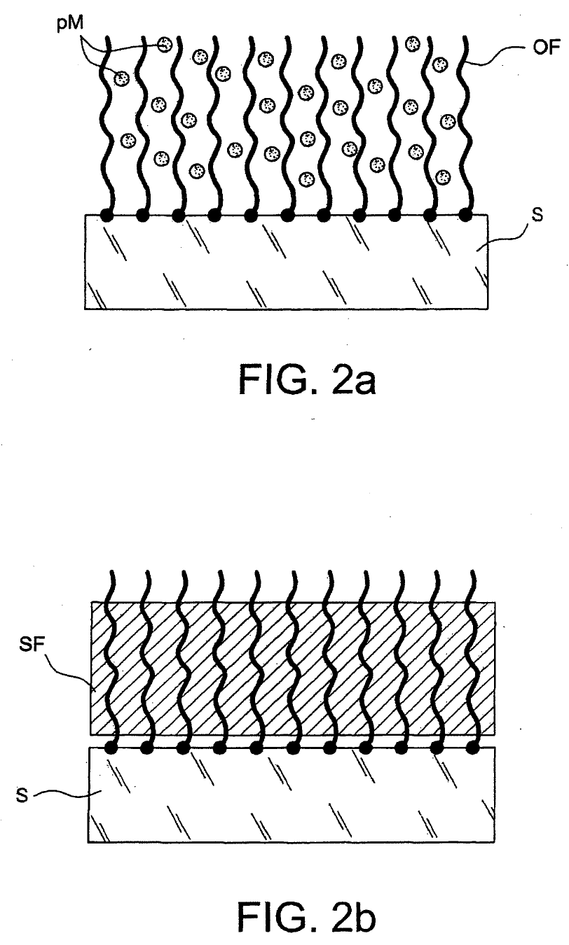

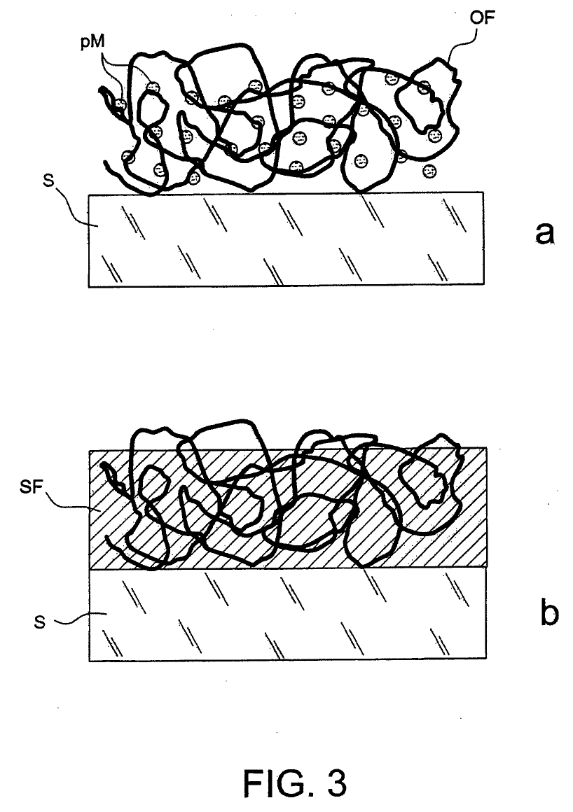

FIG. 15-2 (normal incidence) thus shows the formation of metallic copper within the P4VP film according to the invention. Visual inspection revealed a metal film of great uniformity, despite the fact that the TiN surface was not an equipotential surface, being a semiconductor. Comparison between the spectra obtained at grazing incidence in the case of Protocol 1 (Example 8) and Protocol 2 (present example) shows that there are fewer cupric ions in the case of Protocol 2 than in Protocol 1. This illustrates one of the preferred methods of implementing the invention, in which the filling with the precursors and the reduction are carried out in different baths, thereby making it possible to reprovision the film with the precursors during the reduction. FIG. 16-2 shows the N1s region of the XPS spectrum. Normal incidence, there are two peaks at 397 and 399.5 eV corresponding to the nitrogen atoms of the pyridine rings linked to the metallic (reduced) copper and to the nitrogens of the free pyridine rings, respectively. Unlike Protocol 1 (Example 8), no peak corresponding to nitrogens linked to cupric atoms at around 402 eV is observed, which leaves one to assume that this peak, in FIG. 16-1 (Example 8) was actually due to cupric ions inserted during the reduction, reprovisioning the film over the course of the reduction. The disappearance of the peak at 397 eV in the spectrum obtained at grazing incidence in FIG. 16-1 also shows that metallic copper is present at the bottom of the film, but not on the surface.

As in Example 8, it may be seen that the potential protocol used here for the reduction is not sufficient to reduce all the cupric ions. To do this, it is sufficient to increase the reduction potential and/or the hydrolysis time. However, by choosing the potential protocol of the present example it is possible to illustrate, semiquantitatively, the effect of Protocols 1 and 2 on the supply of precursor ions to the films.

### Example 10

### Formation of a Conformal Organic Film on a 1 μm Etched Feature by Dipping into a Solution Containing Diazonium Salts

The present invention is based on the fact that it is conceivable to produce conformal organic coatings more easily than conformal metal coatings, and that it is possible to exploit this fact to produce conformal metal coatings at points where this is ordinarily impossible or very difficult.

This example illustrates the high-quality conformality that can be achieved using one of the methods of implementation of the invention, in which the chemical grafting of diazonium salts was carried out on a semiconductor surface bearing an etched pattern in the form of a 1 μm grating.

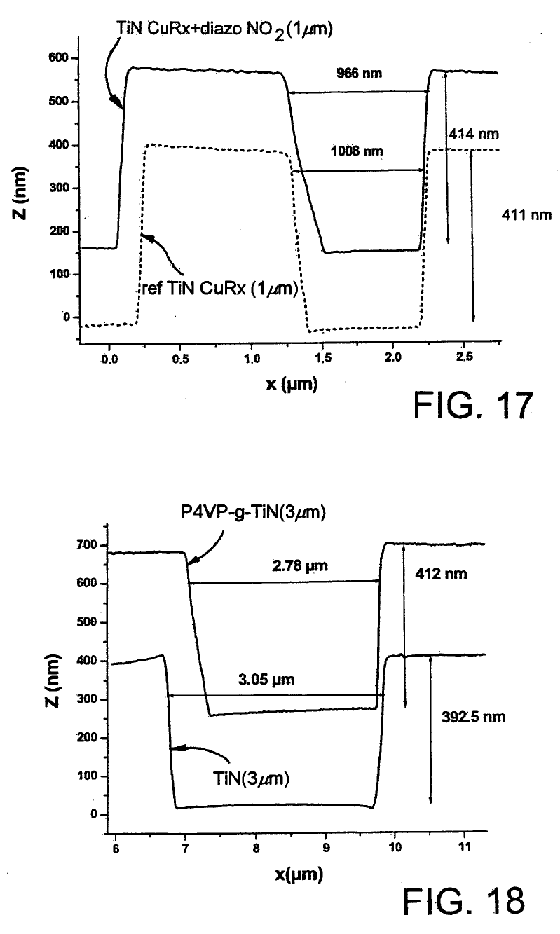

A virgin TiN strip of the same type as that of the previous examples was used for this example. However, unlike the previous examples, this strip had an etched pattern produced using standard processes in the microelectronics industry. The etched pattern consisted of a set of parallel lines 1 μm in width, spaced apart by 1 μm and having a depth of about 400 nm (see FIG. 17 appended hereto).

The strip was treated according to the same protocol as that of Example 6. It was then analysed by atomic force microscopy (nanoscope III AFM: scan speed 0.2 Hz) so as to detect the changes in profile (FIG. 17). The width of the trenches went from 1008 nm to 966 nm, which shows, taking into account the measurement precision on this scale, which is around 15 nm, that a conformal layer of about 34±15 nm in thickness was formed.

It may also be seen that the depth of each trench remains the same, to within the measurement precision, ensuring that there was a conformal coating even at the bottom of the trench.

### Example 11

### Formation of a Conformal Organic Film on a 3 μm Etched Feature by Electrografting of a P4VP Film

This example, which supplements Example 10, illustrates the conformality that can be achieved thanks to polymer films electrografted according to the process of the present invention.

A TiN strip similar, both from the standpoint of the composition and the etching topology, to that of the previous example was used in the present example. However, the etching width was 3 μm, which means trenches 3 μm in width and 3 μm apart (the depth again being equal to 400 nm) (FIG. 18).

The strip was treated according to an electro-grafting protocol similar to that of Example 7, in which 10 wt % divinylbenzene (DVB) was added, and 20 scans at a stopping potential of −3.2 V/(Ag⁺/Ag) were used. The strip thus treated was examined using an AFM in the same manner as in Example 10.

FIG. 18 shows that the width of the trenches goes from 3050±15 nm to 2780±15 nm, i.e. a film thickness on each wall of around 135±15 nm. At the same time it may be seen that the depth of the trench remains the same, to within the measurement precision, which proves that a conformal coating was indeed produced thanks to the electrografted film.

AFM images (respectively modulus and phase images) of wider regions of the surface thus treated have shown that the result is reproducible on large scales.

### Example 12

### Formation of a Conformal Organic Film on 1 μm Etched Features by Electrografting of a P4VP Film

The same methodology as that of Example 11 was applied here to 1 μm etched features, with the formation of a conformal P4VP film. Only 15 voltammetric scans in a solution containing no DVB were used.

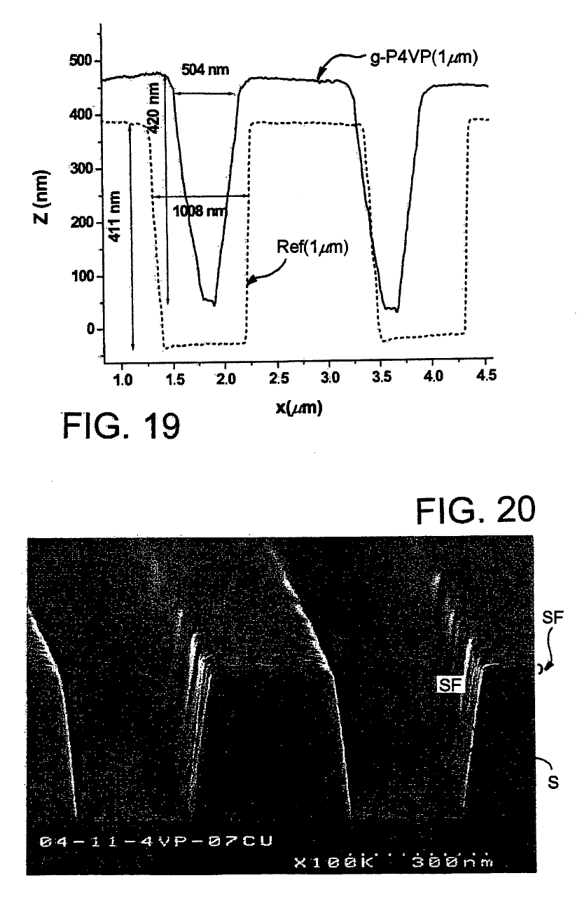

The profiles obtained are shown in FIG. 19 appended hereto. It may be seen that the profile obtained has a “V” shape, characteristic of the profiles obtained when the etching is of a size similar to the indentation of the tip of the AFM microscope used for the measurement. This results in an image in which the effective shape of the profile is convoluted by the geometry of the tip, which was unknown. However, this does mean that the apparent depth, measured on the profiles with the P4VP film, is a lower bound.

Despite this, a depth after electrografting of 420±15 nm was measured, that is to say the same as that before electrografting. The changes in width of the trenches show the formation of a 252±15 nm film conformal to the topology of the substrate, even by large scale on the surface.

### Example 13

### Formation of a Conformal Organic Coating on 300 nm Etched Features by Electrografting of a P4VP Film

This example illustrates the formation of a conformal P4VP film, filled with metal precursors, on 300 nm etched features (i.e. those having trenches 300 nm in width spaced 300 nm apart, the depth again being 400 nm). It therefore shows the potential of the invention for surfaces of high aspect ratio. It also shows the potential of electrografting as method of implementation for working at scales compatible with the current etching resolutions and those in the future in the microelectronics field.

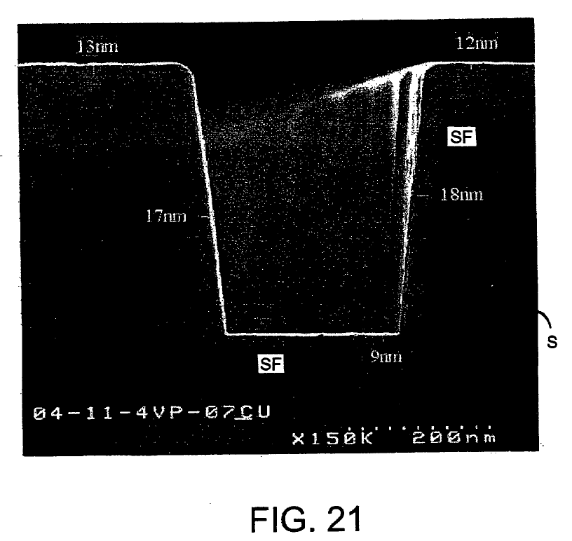

The TiN strips were comparable to those used above. The electrografting methodology was the same as that used for Example 7 (with only 10 voltammetric scans). The P4VP films obtained were filled with cupric ions using the same methodology as that used in Examples 8 and 9. The reduction of the precursors was intentionally not carried out, so as to obtain films filled with copper sulphate as precursor of the metallic material, and therefore insulating films. This made it easier to demonstrate the formation of the layer by scanning electron microscopy (SEM), as illustrated in FIGS. 20 and 21 appended hereto, on the trench of the strip that was fractured so that the fracture edge lost the direction of the trenches.

These images were produced with an acceleration voltage of 20 kV, that is to say a high voltage at which the organic film necessarily cannot be seen. However, at this voltage an insulating coating results in a very bright contrast, unlike the sufficiently conducting regions that result in a darker contrast.

FIGS. 20 and 21 show the topology obtained, at two different focusings, and illustrate the conformality obtained both on the walls and the bottom of the trenches.

A sharp difference in contrast is observed between, on the one hand, the surface, and on the other hand, the body of the silicon trenches, and finally the barrier layer, clearly visible in FIG. 20 and covering the entire topology.

FIG. 21 is an enlargement of one region of the trenches in the strip, in which it may be clearly seen that there is a difference in contrast between the barrier layer (which is dark) and a highly conformal upper layer (which is bright) due to the P4VP film filled with the salt of the metal precursors.

It should be noted on passing that the contrast of the surface remaining beneath the film is darker, which shows that the film having a brighter contrast is not the barrier layer but indeed the seed film of the present invention.

### Example 14

### Formation of a Conformal Organic Film on 300 nm Etched Features by Electrografting of Diazonium Salts

This example illustrates the formation of an ultraconformal organic film obtained by electrografting of a diazonium salt on an etched silicon surface (200 nm etched features with a spacing of 300 nm and a depth of 400 nm), which is coated with a 10 nm thick TiN barrier layer conformal with the etching. It there therefore shows the very high level of conformality that can be achieved thanks to electrografted organic films, especially on surfaces having high aspect ratios, and illustrates the topology on or in which the metal seed films may be created. It also shows the potential of electrografting as a method of implementation for working on scales compatible with the current and future etching resolutions in the microelectronics field.

An organic film was electrografted onto etched TiN strips identical to those used in the previous example using the following protocol: the strip was immersed in a 5×10⁻³ mol/l solution of 4-nitrophenyl-diazonium tetrafluoroborate in a 5×10⁻² mol/l TEAP solution in acetonitrile. Seven voltammetric scans at 20 mV/s, between +0.25 and −2.00 V/(Ag⁺/Ag) were then applied to this surface, used as reference electrode, in the presence of a gold strip connected as counterelectrode.

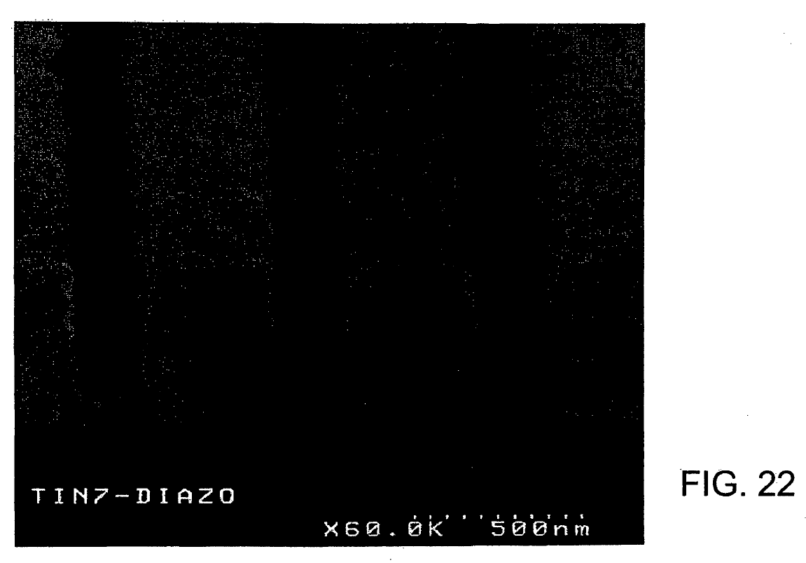

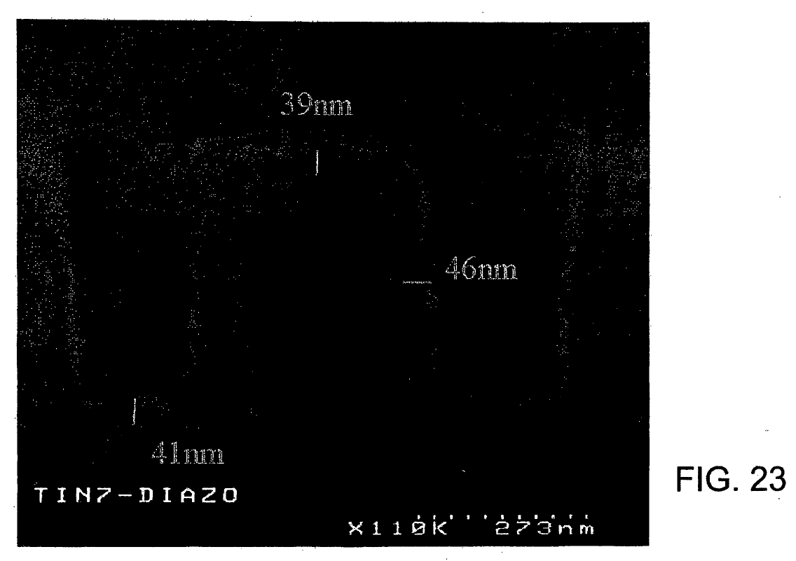

The strip thus treated was ultrasonically rinsed for 2 minutes in acetone and then dried in argon. It was then fractured, in such a way that the fracture was at right angles to the etching lines. The trenches thus obtained were analysed using a scanning electron microscope, as illustrated in FIGS. 22 and 23.

FIG. 22 clearly shows the silicon substrate provided with its thin titanium nitride barrier layer (which appears bright), coated with the highly conformal organic layer obtained by the process, both on the walls and the bottom of the trenches. FIG. 23 completes this analysis, showing that the thickness of the organic coating obtained was 46 nm on the walls, 41 nm at the top of the etched trenches and 39 nm at the bottom of the etched trenches. These results in fact show a completely and strictly uniform and conformal coating to within the precision of the SEM measurements, which is estimated to be 5 nm.

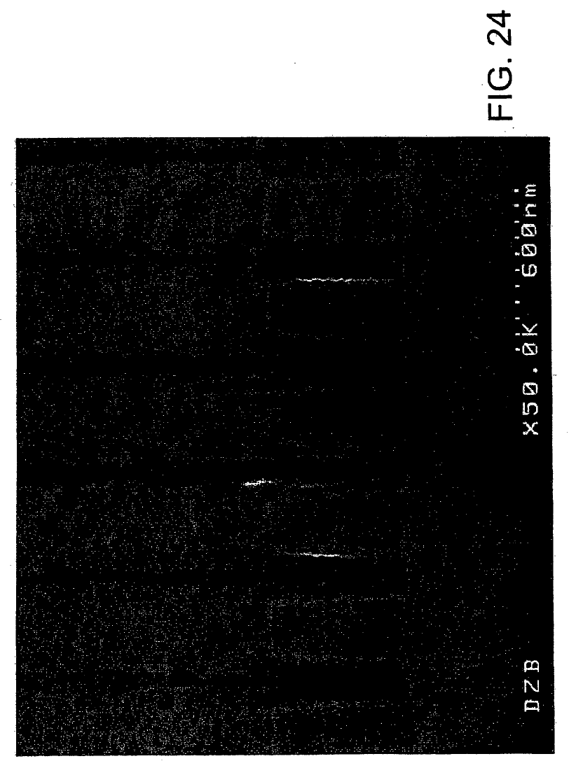

FIG. 24 shows the effect produced by the same treatment on finer (0.12 μm) etched features in TiN. Again excellent conformality is observed, although the film thicknesses obtained, which are again about 40 nm, are in this case poorly matched to the resolution of the etching. However, as was seen in the descriptive part, it is easy to control the thickness of an organic film obtained from diazonium salts, especially by means of the number of scans, the final potential of the scan or the concentration of precursor salt. The additional lesson FIG. 24 is nevertheless that the electrografting of diazonium salts from organic solutions does allow very effective wetting, even at very high aspect ratios, which is probably one of the reasons contributing both to the effectiveness and the flexibility of the process.

### Example 15

### Formation of a Uniform P4VP Film on Tantalum Nitride

This example illustrates the formation of a metal (Cu) seed film obtained from a uniform P4VP organic film obtained by electrografting on a plane tantalum nitride (TaN) surface covered with its oxide layer. This example illustrates the versatility of electrografting, which is capable of being adapted to surfaces having oxide layers, provided that they remain at least electrically semiconductive.

A silicon strip coated with a 1 μm layer of silicon oxide (SiO₂) and with a tantalum nitride barrier layer surface-enriched with tantalum (which is more conducting), the overall barrier layer having a thickness of around 25 nm, was used as working electrode.

The electrode was immersed in a solution containing 40% 4VP and 5×10⁻² mol/l of TEAP in DMF. Sixty voltammetric scans between −0.9 and −4.0 V/(Ag⁺/Ag) were applied to the electrode at 200 mV/s, with a graphite counterelectrode. The surface thus treated was ultrasonically rinsed for 2 minutes in acetone and then immersed for 6 minutes at room temperature in an electroplating solution identical to that used in Example 8. After this time had elapsed, the strip was plated under potentiostatic conditions at −0.5 V/SCE for 6 minutes.

Finally, the strip was ultrasonically rinsed for 2 minutes in deionized water and then ultrasonically rinsed for 2 minutes in acetone.

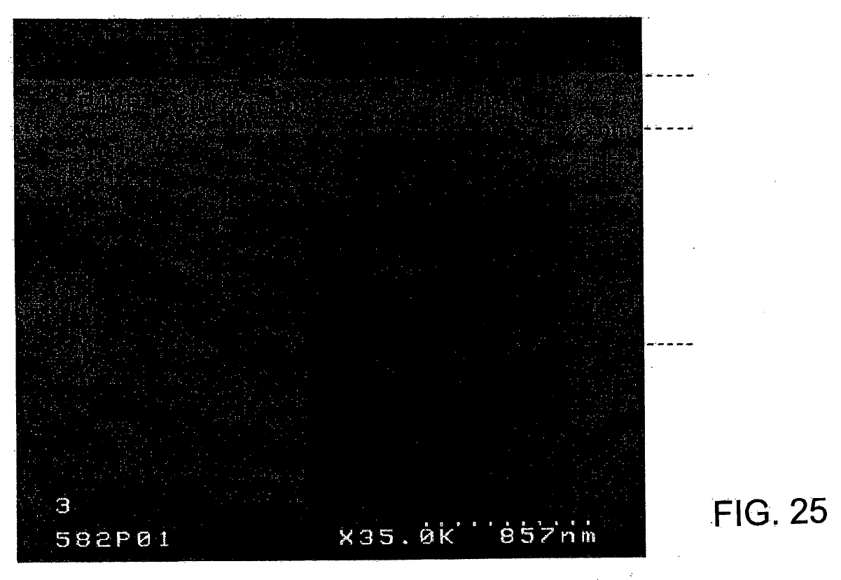

FIG. 25 shows the trench obtained after the treated strip was fractured. In the figure may be clearly distinguished, from the bottom upwards, the silicon, the 1 μM SiO₂ layer, the very thin TaN/Ta hybrid barrier layer and a 278 nm layer. Surface analysis showed that this was indeed a layer of plated P4VP impregnated with metallic copper.

### Example 16

### Growth of a Copper Film on a Seed Layer According to the Invention, Produced on a TiN Surface

This example illustrates, in a similar manner to that demonstrated in Example 2 with a P4VP film electrografted onto metal, the conformal growth of a metal film starting from a seed layer obtained according to the invention. The illustration relates here to the growth of a copper film on a TiN surface used as barrier on an etched silicon surface.

An etched silicon strip coated with a titanium nitride (TiN) barrier layer was conformally coated with an organic film by electrografting a diazonium salt, namely 4-nitrophenyldiazonium tetrafluoroborate, using a protocol comparable to that of Example 14, with ten voltammetric scans between +0.25 and −2.5 V/(Ag⁺/Ag) at 20 mV/s with graphite counterelectrode. The strip thus treated was ultrasonically rinsed for 2 minutes in acetone and then immersed for 6 minutes at room temperature in an electroplating solution identical to that of Example 8. After this time, the strip was biased under potentiostatic conditions at −0.5 V/SCE for 8 minutes and then three voltammetric scans between 0 and −2.5 V/SCE were applied to it at 100 mV/s. The strip was then ultrasonically rinsed for 2 minutes in deionized water and finally untrasonically rinsed for 2 minutes in acetone and then dried in argon before being analysed by SEM.

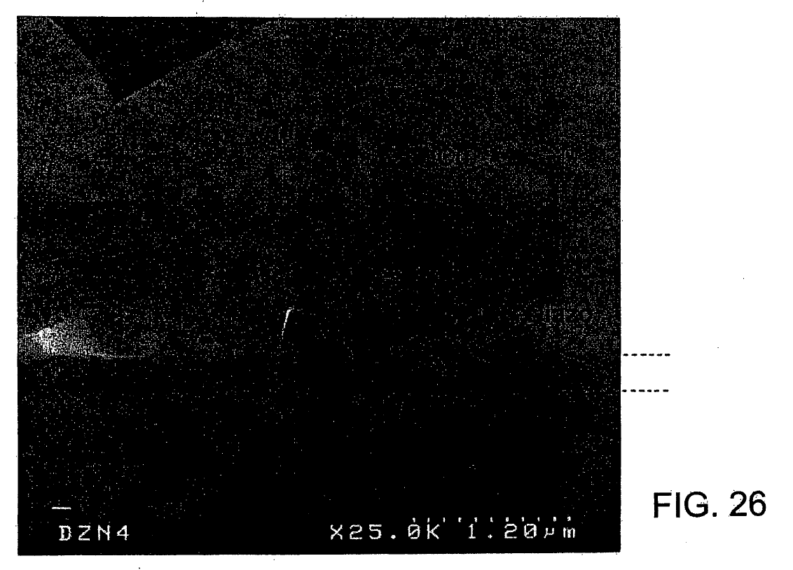

FIG. 26 shows an SEM view, with a magnification of ×25000, of the trench obtained by fracturing the strip along a line of fracture perpendicular to the direction of the etched features. This figure clearly shows, from the bottom upwards, the silicon of the substrate, the TiN barrier layer, the diazo organic layer, which conforms very closely to the etched feature located in the middle of the image, and a thick copper layer (part of the surface of which may be seen in the top left of the image). It may seen that the interface between the organic seed layer and the copper layer is perfectly controlled, over the entire length of the profile, and especially in the regions of high asperity, such as around the etched feature.

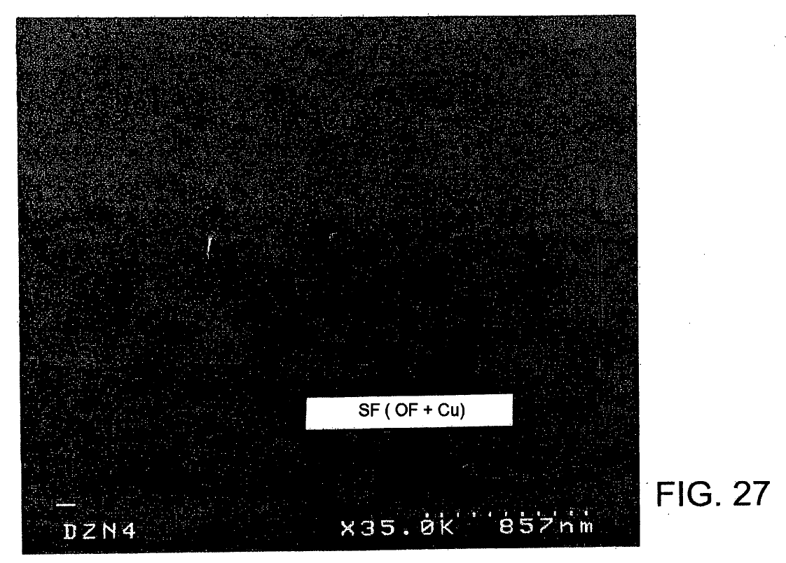

FIG. 27 shows the result obtained at another point on the same specimen, in a region possessing 120 nm etched features. It may be seen that the copper has grown from the bottom of the etched features, thereby showing the beneficial effect provided by the seed layer obtained according to the invention.

### Additional Examples

### Example 17

This particular example illustrates the complete formation of a complete seed layer by the electrografting of an organic layer, the insertion of copper precursors into this layer, the reduction of the precursors in order to give a hyperconformal metallic copper seed layer and its use for filling trenches in an interconnected structure of the damascene type.

The substrates consisted of 2×4 cm² silicon test coupons coated with a layer of silicon oxide (a dielectric) and with a 10 nm layer of MOCVD TiN as copper diffusion barrier. These substrates were structured, having 200 nm wide trenches, with a spacing of 200 nm and a depth of about 400 nm. No specific cleaning or surface treatment was carried out before the electrografting. The experiments were not carried out under clean room conditions.

An electrografted film was produced from a solution of aryldiazonium tetrafluoroborate substituted with ammonium groups in acetonitrile, in the presence of tetraethylammonium perchlorate (TEAP) as support electrolyte.

The electrografting was carried out at a fixed potential in a 3-electrode set-up. The TiN surface was used as working electrode (connected using a crocodile clip), the counterelectrode was a graphite surface and the reference electrode was an Ag⁺/Ag electrode, these being connected to a Model 283 EGG potentiostat (from Princeton Applied Research).

As in the previous examples, the electrografted film may be seen to be hyperconformal to the original surface, with a uniform thickness of about 40 nm.

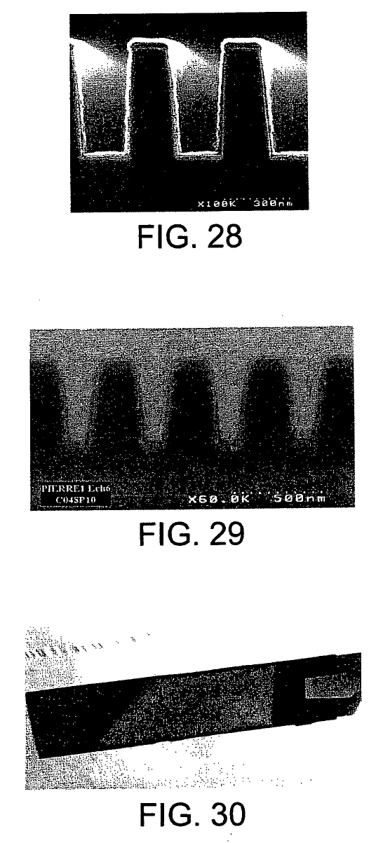

Metal precursors were inserted into the electrografted layer in the following manner: the TiN strips bearing the electrografted films were immersed in a solution containing palladium (Pd(II)) ions. It was found that the palladium was inserted into the films thanks to the complexation with the amine groups present in the electrografted films. The strips were then treated with dimethylaminoborane (DMAB) in order to reduce the palladium to the metallic state within the film. The strips thus treated were immersed in an electroless copper solution. It was found that a very thin copper layer was uniformly deposited, this being catalysed by the metallic palladium aggregates present within the electrografted film. Observation in a high-resolution scanning electron microscope of the structured TiN substrate showed that the copper layer was, just like the original electrografted layer, hyperconformal, with a uniform thickness of about 20 nm (FIG. 28 appended hereto).

Copper was then electroplated onto the seed layer thus obtained using a solution of copper sulphate in sulphuric acid under galvanostatic conditions, namely about 7 mA/cm². A uniform copper coating was observed to rapidly form on the pretreated surface.

The substrate was then cleaved and the trenches in the fractured zone were examined in a high-resolution scanning electron microscope. This showed perfect filling of the trenches with copper, with very few voids, the seed layer having fulfilled its role perfectly (FIG. 29 appended hereto).

### Example 18

This example illustrates the complete formation of a seed layer by electrografting from a mixture of vinyl monomers and copper precursors, in one and the same bath, and its use for filling trenches in an interconnected structure of the damascene type.

The substrates were flat 2×4 cm² silicon coupons coated with a 400 nm layer of SiO₂ and with a 10 nm TiN layer obtained by MOCVD. As previously, no specific cleaning or surface treatment was carried out before the electrografting. The experiments were not carried out under clean room conditions.

A film electrografted onto these substrates was produced using them as working electrode in a three-electrode set-up similar to that of the previous example. The electrografting solution was a solution of 4-vinylpyridine and cuprous bromide in dimethylformamide in the presence of tetraethylammonium perchlorate (TEAP) as support electrolyte. The coupons were dipped up to two-thirds of their length in the electrografting bath and contact was made with these substrates using a crocodile clip, which was not immersed in the bath.

Spectacular results were obtained. Uniform metallization was observed (the measurements at the meniscus and at 5 cm from the meniscus were identical, to within the precision of an atomic force microscope (AFM)), even at a few centimetres from the contact electrode.

A complementary experiment was then preformed in which the substrate was prescratched horizontally at about one fifth of its length starting from the bottom, sufficiently deeply to reach the subjacent SiO₂ layer. The coupon thus scratched was immersed in the electro-grafting bath, with the scratch at the bottom, so that the scratch was in the solution. As previously, the coupon was immersed up to two-thirds of its length and the contact (clip) was not immersed in the bath.

By carrying out the electrografting under the voltammetric conditions as previously, a uniform copper coating was observed starting from the meniscus right down to the scratch, but nothing entered the scratch and the bottom of the strip—that part of the TiN surface which was no longer electrically connected was not coated. This confirmed that the growth is indeed electrically activated and that coating is not obtained by a currentless chemisorption process (FIG. 30 appended hereto).

Likewise, on the unscratched plane substrate, AFM thickness measurements showed that the copper coating was very uniform, therefore indicating a very low sensitivity to the ohmic drop of the semiconductive TiN substrate. Even in the presence of the copper precursor, the growth mechanism had the characteristics of an electro-initiated electrografting reaction.

Furthermore, the same trials but without the organic precursor (4-vinylpyridine) did not show a direct metal coating on the TiN barrier, except level with the meniscus, which is attributed to the known effects of the ohmic drop of the substrate.

However, it should be noted that the measurement currents were rapidly much higher (of the order of several mA) than was expected from a simple electro-initiation process. Most of the current flowing through the electrode corresponded to the reduction of the cuprous ions to metallic copper on the nascent seed layer formed initially. The residual currents due to the electrografting reactions were probably not detectable when copper growth beyond the seed layer was underway.

Finally, complementary tests were carried out on patterned specimens (trenches 0.22 μm in width, with a spacing of 0.22 μm and a depth of 0.4 μm) in order to study the morphological properties of the coatings. The same voltammetric conditions were applied, in the same baths and in the same set-up. Once again, a uniform macroscopic copper coating was observed.

The coupons were dipped up to two-thirds into the bath, so that the seed layer was deposited over two-thirds of the coupon, the last third being untreated TiN.

SEM observations on the treated regions clearly showed a metal film on the barrier layer, this film being perfectly continuous and, highly advantageously, conformal with the surface. This key result is in line with the high degree of conformality obtained with just an electrografted layer.

These seed layers were used to initiate electrochemical deposition (ECD) of copper from a commercial bath. For this purpose, electrical contact was made on the previously electrografted part of the specimens. Thus, during copper deposition by ECD, the specimen was inverted and that region of the specimen that had previously been electrografted was exposed to the chemical copper electrodeposition bath.

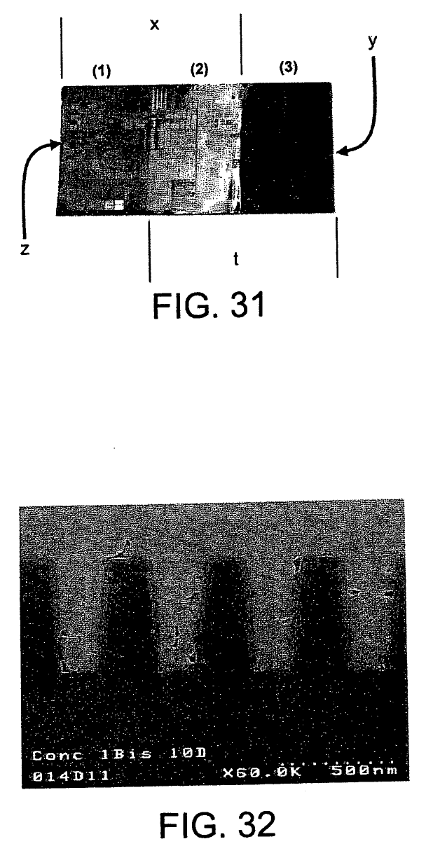

After copper electroplating, the appearance of the specimens was very interesting—a pretty metallization layer of uniform copper was observed on the central third of the coupon, that is to say on the surface of the specimen that had been previously electrografted, whereas no copper was deposited on the TiN barrier layer. In addition, as previously, it was on the upper third of the electrografted strip that the contact was made, this contact not being immersed in the ECD bath and being located more than 1 cm from the meniscus. The seed layer was therefore sufficiently continuous and conductive to allow ECD copper deposition on the treated region by immersion in the bath (FIG. 31). In FIG. 31, x represents that portion of the strip in which the electrografting was carried out, y represents the contact region for the electrografting, represents the contact for electroplating and t represents that part of the strip that was electroplated.

From a microscopic standpoint, the SEM examination of the copper filling was carried out on specimen sections produced by nanomachining (FIB (focused ion beam)). Satisfactory trench filling was observed, even though a few voids did appear. The inventors believe that, under more favourable conditions (clean room, improved control of the chemical and barrier surfaces, etc.), the trench filling performance may be substantially improved (FIG. 32 appended hereto).

1. Process for coating a surface of a substrate with a seed film of a metallic material, the said surface being an electrically conductive or semiconductive surface and having recesses and/or projections, the said process comprising the following steps:
an organic film is placed on the said surface, the said film adhering to the said surface and having a thickness such that the free face of this film conformally follows the recesses and/or projections of the said electrically conductive or semiconductive surface on which it is placed;
a precursor of the metallic material is inserted within the said organic film placed on the said surface, at the same time as, or after, the step consisting in placing the said organic film on the said surface; and
the said precursor of the metallic material inserted within the said organic film is converted into the said metallic material so that this metallic material forms conformally at the said recesses and/or projections of the said surface to be coated and within the said organic film in order to form, with the latter, the said seed film.

2. Process for fabricating interconnects for an integrated circuit in microelectronics, the said interconnects consisting of a metallic material, the said process comprising, in the following order, the steps consisting in:
a) etching interconnect patterns in a dielectric substrate, the said patterns forming recesses and optionally projections on and/or through the said substrate;
b) depositing a conducting barrier layer on the said etched dielectric substrate, which layer prevents the metallic interconnect material from migrating into the said substrate, the said barrier layer having a thickness such that the free face of this layer conformally follows the interconnect patterns of the said substrate on which the said layer is deposited;
c) coating the conducting barrier layer deposited on the etched substrate with a seed film of a metallic material by means of the process of claim 1; and
d) filling the recesses with the said metallic material starting from the said seed film in order to form the said metal interconnects made of the said metallic material.

3. Process according to claim 1 or 2, in which the organic film is an organic macromolecule or a polymer.

4. Process according to claim 1 or 2, in which the organic film is obtained from a chemical precursor thereof, chosen from the group consisting of vinyl monomers, methacrylic or acrylic acid ester monomers, functionalized or unfunctionalized diazonium salts, functionalized or unfunctionalized sulphonium salts, functionalized or unfunctionalized phosphonium salts, functionalized or unfunctionalized iodonium salts, precursors for polyamides obtained by polycondensation, cyclic monomers that can be cleaved by nucleophilic or electrophilic attack, and mixtures thereof.

5. Process according to claim 1 or 2, in which the organic film is obtained from one or more activated vinyl monomers of the following structure (I): 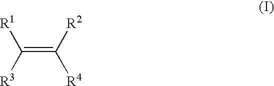
in which R¹, R², R³ and R⁴ are organic groups chosen independently of one another from the group consisting of the following organic functions: hydrogen, hydroxyl, amine, thiol, carboxylic acid, ester, amide, imide, imidoester, acid halide, acid anhydride, nitrile, succinimide, phthalimide, isocyanate, epoxide, siloxane, benzoquinone, benzophenone, carbonyl-diimidazole, p-toluenesulphonyl, p-nitrophenyl chloro-formate, ethylene, vinyl and aromatic.

6. Process according to claim 5, in which at least one of R¹, R², R³ and R⁴ is a functional group that can trap the precursor of the metallic material.

7. Process according to claim 1 or 2, in which the organic film is a polymer obtained by the polymerization of a vinyl monomer chosen from the group consisting of vinyl monomers, such as acrylonitrile, methacrylonitrile, methyl methacrylate, ethyl methacrylate, butyl methacrylate, propyl methacrylate, hydroxyethyl methacrylate, hydroxypropyl methacrylate, glycidyl methacrylate, acrylamides, and especially aminoethyl, aminopropyl, aminobutyl, aminopentyl and aminohexyl methacrylamides, cyanoacrylates, polyethylene glycol dimethacrylate, acrylic acid, methacrylic acid, styrene, p-chlorostyrene, N-vinylpyrrolidone, 4-vinylpyridine, vinyl halides, acryloyl chloride, methacryloyl chloride, and derivatives thereof.

8. Process according to claim 1, in which the organic film includes functional groups that are ligands for precursor metal ions of the metallic material.

9. Process according to claim 1 or 2, in which the organic film is deposited on the surface by means of a technique chosen from electro-mediated polymerization, spin coating, dip coating and spraying.

10. The process according to claim 1 or 2, in which, owing to the dimensions of the recesses and/or projections, the organic film is placed on the surface with a thickness ranging from 0.001 to 500 μm or from 0.001 to 100 μm.

11. Process according to claim 1 or 2, in which, owing to the dimensions of the recesses and/or projections, the organic film is placed on the surface with a thickness ranging from 0.001 to 10 μm.

12. Process according to claim 1 or 2, in which the precursor of the metallic material is chosen in such a way that it can be converted into the said metallic material by a technique chosen from precipitation, crystallization, crosslinking, aggregation and electroplating.

13. Process according to claim 1 or 2, in which the precursor of the metallic material is an ion of the said metallic material.

14. Process according to claim 1 or 2, in which the precursor of the metallic material is chosen from the group consisting of copper ions, zinc ions, gold ions and ions of tin, titanium, vanadium, chromium, iron, cobalt, lithium, sodium, aluminium, magnesium, potassium, rubidium, caesium, strontium, yttrium, niobium, molybdenum, ruthenium, rhodium, palladium, silver, cadmium, indium, lutetium, hafnium, tantalum, tungsten, rhenium, osmium, iridium, platinum, mercury, thallium, lead, bismuth, lanthanides and actinides.

15. Process according to claim 1 or 2, in which the metallic material is copper or platinum.

16. Process according to claim 1 or 2, in which the precursor is in the form of metal particles or aggregates, optionally encapsulated in a protective gangue, chosen from the group consisting of micelles, polymer nanospheres, fullerenes, carbon nanotubes, cyclodextrins, and in which the step of converting the precursor into the said metallic material is carried out by releasing the metal particles or aggregates from their gangue.

17. Process according to claim 1 or 2, in which the precursor of the metallic material is inserted into the organic film by means of a dipping or spin coating technique.

18. Process according to claim 1 or 2, in which the precursor of the metallic material is inserted within the organic film, placed on the surface, by means of an insertion solution which is both a solvent for the precursor of the metallic material and a solvent for the organic film, the said insertion solution including the said precursor of the metallic material.

19. Process according to claim 1 or 2, in which the precursor of the metallic material is inserted within the organic film, placed on the surface, by means of an insertion solution which is both a solvent or a dispersant for the precursor of the metallic material and a solution that swells the first material, the said insertion solution including the said precursor of the metallic material.

20. Process according to claim 1 or 2, in which the step consisting in inserting the precursor of the metallic material within the organic film placed on the said surface is carried out at the same time as the step consisting in placing the organic film on the said surface by means of an insertion solution comprising both the said organic film or a precursor of the said organic film and the precursor of the metallic material.

21. Process according to claim 1 or 2, in which the step of inserting the precursor of the metallic material into the organic film is carried out by means of a first solution containing the precursor of the metallic material, and in which the step of converting the metallic material into the said metallic material within the organic film is carried out by means of a second solution that does not contain the said precursor of the metallic material.

22. Process according to claim 21, in which the steps of inserting the precursor of the metallic material into the organic film and of converting the said precursor into the said metallic material are repeated several times alternately.

23. Process according to claim 17, 18, 19 or 20, in which the insertion solution is an aqueous solution.

24. Process according to claim 1 or 2, in which the precursor of the metallic material is converted into the said metallic material by electroplating, precipitation or electroless conversion.

25. Process according to claim 1 or 2, in which the surface is a conductive or semiconductive surface, the organic film consists of a vinyl polymer and the metallic material is copper or platinum, the precursor of the metallic material being a copper or platinum ion.

26. Process according to claim 1, in which the surface having recesses and projections is a surface of a microchip.

27. Process according to claim 1, in which the said substrate includes on its electrically conductive and/or semiconductive surface having recesses and/or projections, a barrier layer that prevents the metallic material from migrating into the said substrate, the said barrier layer having a thickness such that the free face of this layer conformally follows the recesses and/or projections of the said substrate on which the said barrier layer is deposited.

28. Process according to claim 27, in which, before the step consisting in placing the organic film on the said surface of the substrate, it furthermore includes a step consisting in depositing the said barrier layer.

29. Process according to claim 2 or 27, in which the barrier layer is a layer of a material chosen from the group consisting of the following: titanium; tantalum; titanium, tantalum and tungsten nitrides; titanium and tungsten carbides; tantalum, tungsten and chromium carbonitrides; silicon-doped titanium or tantalum nitride; and ternary alloys comprising cobalt or nickel alloyed with a refractory such as molybdenum, rhenium or tungsten, and with a dopant such as phosphorus or boron.

30. Process according to claim 2 or 27, in which the barrier layer is deposited by a technique chosen from the group consisting of chemical vapour or physical vapour deposition techniques.

31. Process according to claim 2 or 27, in which the barrier layer is a TiN or TiN(Si) layer and the metallic material is copper.

32. Process according to claim 2 or 27, in which the substrate is an inter-level insulating layer for the fabrication of an integrated circuit.

33. Process according to claim 2 or 27, in which the step of filling the recesses is carried out by means of an electroless plating technique from a solution of the precursor of the metallic material, or by means of an electroplating technique for depositing the said metallic material.

34. Process according to claim 2 or 27, which includes, after the step of filling the recesses with the metallic material, a step of polishing the excess metallic material lying on the said surface.

35. Use of the process according to claim 1 for fabricating an interconnection element in microelectronics.

36. Use of the process according to claim 1 or 2 for fabricating an electronic microsystem.

37. Integrated circuit that can be obtained by implementing the process of claim 2.

38. Electronic microsystem that can be obtained by implementing the process of claim 2.

39. Integrated circuit, characterized in that it includes a seed film obtained by the process according to claim 1.

40. Microsystem, characterized in that it includes a seed film obtained by the process according to claim 1.

41. Process for galvanically plating a surface, the said surface being an electrically conductive or semiconductive surface and having recesses and/or projections, the said process comprising the following steps:
coating of the said surface with a seed film of a metallic material using the process of claim 1; and
galvanic deposition of a metal layer of the said metallic material starting from the said seed film obtained.
